(19) United States
(12) Patent Application Publication
(10) Pub. No.: US 2026/0255715 A1
(43) Pub. Date: Aug. 27, 2026

(54) IMAGE SENSOR AND CAPACITOR INCLUDED IN THE SAME

(71) Applicant: Samsung Electronics Co., Ltd., Suwon-si (KR)

(72) Inventors: Seungho LEE, Suwon-si (KR); Yongsoon PARK, Suwon-si (KR); Jungsan KIM, Suwon-si (KR); Taemin KIM, Suwon-si (KR)

(73) Assignee: Samsung Electronics Co., Ltd., Suwon-si (KR)

(21) Appl. No.: 19/401,678

(22) Filed: Nov. 26, 2025

(30) Foreign Application Priority Data
Feb. 21, 2025 (KR) 10-2025-0023210

(51) Int. Cl. H10F 39/00; H01L 23/522; H10F 39/18

(52) U.S. Cl. CPC H10F 39/811; H10F 39/182; H10F 39/809; H10W 20/496

(57) ABSTRACT

An image sensor according to at least one example embodiment includes a substrate, a plurality of pixel regions, and a wiring portion electrically connected to the plurality of regions. Each of the plurality of pixel regions includes a photodiode in the substrate and a pixel circuit at a first surface of the substrate. The wiring portion includes a capacitor. The capacitor includes a plurality of electrodes and an insulation layer between the plurality of electrodes. The plurality of electrodes include a first electrode group and a second electrode group electrically insulated from each other. At least one of the first electrode group and the second electrode group includes a plurality of electrode layers electrically connected to each other. The capacitor includes a side overlap portion in which the first electrode group and the second electrode group are stacked at a side surface of the capacitor.

### CROSS-REFERENCE TO RELATED APPLICATION

This application claims priority to and the benefit of Korean Patent Application No. 10-2025-0023210 filed with the Korean Intellectual Property Office on Feb. 21, 2025, the entire contents of which are incorporated herein by reference.

### BACKGROUND

### (a) Field

The present disclosure relates to an image sensor and a capacitor included in the same, and more specifically, to an image sensor having an improved structure and a capacitor included in the same.

### (b) Description of the Related Art

An image sensor is a semiconductor device that is configured to convert optical images into electrical signals. The image sensors may be classified into charge coupled device (CCD) type image sensors based on silicon semiconductors and complementary metal oxide semiconductor (CMOS) type image sensors (CIS).

Among these, the CMOS type image sensors may be driven by a relatively simple method using, e.g., a signal processing circuit, and the signal processing circuit may be integrated on a single chip in the CMOS type image sensors. Therefore, the CMOS type image sensors may be downsized and have a low power consumption, and thus, may be applied to products with a limited battery capacity. With the advancement of the electronics industry, various studies are continuing to improve the performance of the CMOS type image sensors.

### SUMMARY

The present disclosure attempts to provide an image sensor capable of enhancing performance and a capacitor included in the same.

An image sensor according to at least one example embodiment includes a substrate, a plurality of pixel regions, and a wiring portion. The substrate has a first surface and a second surface, the second surface opposite to the first surface. Each of the plurality of pixel regions includes a photodiode in the substrate and a pixel circuit at the first surface of the substrate. The wiring portion is on the first surface of the substrate and is electrically connected to the pixel circuit. The wiring portion includes a capacitor. The capacitor includes a plurality of electrodes and an insulation layer between the plurality of electrodes. The plurality of electrodes include a first electrode group and a second electrode group, and the insulation layer electrically insulates the first electrode group from the second electrode group. At least one of the first electrode group and the second electrode group includes a plurality of electrode layers electrically connected to each other. The capacitor includes a side overlap portion in which the first electrode group and the second electrode group are stacked at a side surface of the capacitor.

An image sensor according to at least one example embodiment includes a substrate, a plurality of pixel regions, and a wiring portion. The substrate has a first surface and a second surface, the second surface opposite to the first surface. Each of the plurality of pixel regions includes a photodiode in the substrate and a pixel circuit at or on the first surface of the substrate. The wiring portion is on the first surface of the substrate and is electrically connected to the pixel circuit. The wiring portion includes a capacitor. The capacitor includes a plurality of electrodes and an insulation layer between the plurality of electrodes. The capacitor includes a side overlap portion in which the plurality of electrodes are stacked at a side surface of the capacitor. The plurality of electrodes include at least a first electrode and a second electrode. The first electrode includes a first horizontal portion. The second electrode includes a second horizontal portion and a second side portion, the second horizontal portion on the first horizontal portion and the second side portion on a side surface of the first horizontal portion. The wiring portion includes a capacitor contact via passing through at least one of the first horizontal portion and the second horizontal portion and electrically connected to the first electrode or the second electrode.

A capacitor according to at least one example embodiment includes a plurality of electrodes and an insulation layer between the plurality of electrodes. The plurality of electrodes include a first electrode group and a second electrode group, the second electrode group electrically insulated from the first electrode group. At least one of the first electrode group and the second electrode group includes a plurality of electrode layers electrically connected to each other. The capacitor includes a side overlap portion in which the first electrode group and the second electrode group are stacked at a side surface of the capacitor.

According to at least one example embodiment, a capacitor may include a side overlap portion at a side surface at an edge (e.g., an outer edge) of the capacitor, and a capacitance of the capacitor may increase without a major change in a manufacturing process. Accordingly, noise of the image sensor may be improved and thus performance of the image sensor may be improved.

### BRIEF DESCRIPTION OF THE DRAWINGS

FIG. 1 is a block diagram schematically illustrating an image sensor according to at least one example embodiment.

FIG. 2 is a circuit diagram of a pixel array that is included in the image sensor illustrated in FIG. 1.

FIG. 3 is a partial cross-sectional view illustrating an image sensor according to at least one example embodiment.

FIG. 4 is a rear plan view schematically illustrating the image sensor illustrated in FIG. 3.

FIG. 5 is a rear plan view schematically illustrating a capacitor in each pixel region of the image sensor illustrated in FIG. 4.

FIG. 6 is a partial cross-sectional view taken along a line B-B′ in FIG. 5.

FIG. 7 is a partial cross-sectional view taken along a line D-D′ in FIG. 5.

FIG. 8 is a partial cross-sectional view taken along a line E-E′ in FIG. 5.

FIG. 9 is a rear plan view schematically illustrating a first electrode of the capacitor in each pixel region of the image sensor illustrated in FIG. 4.

FIG. 10 is a rear plan view schematically illustrating a second electrode of the capacitor in each pixel region of the image sensor illustrated in FIG. 4.

FIG. 11 is a rear plan view schematically illustrating a capacitor in each pixel region of an image sensor according to at least one example embodiment.

FIG. 12 is a rear plan view schematically illustrating a capacitor in each pixel region of an image sensor according to at least one example embodiment.

FIG. 13 is a rear plan view schematically illustrating a capacitor in each pixel region of an image sensor according to at least one example embodiment.

FIG. 14 is a partial cross-sectional view illustrating an image sensor according to at least one example embodiment.

FIG. 15 is a partial cross-sectional view illustrating an image sensor according to at least one example embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the example embodiments provided herein.

A portion unrelated to the description is omitted in order to clearly describe the present disclosure, and same or similar components are denoted by a same reference numeral throughout the present specification.

Further, since a size and/or a thickness of a portion, a region, a member, a unit, a layer, a film, a substrate, or the like illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or the like may be enlarged or exaggerated for convenience of explanation and/or simple illustration. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when a component such as a portion, a region, a member, a unit, a layer, a film, a substrate, or the like is referred to as being “on” or “above” another component, it may be directly on another component or an intervening component may also be present. In contrast, when a component is referred to as being “directly on” another component, there is no intervening component. Further, when a component is referred to as being “on” or “above” a reference component, a component may be disposed on or below the reference component, and does not necessarily be “on” or “above” the reference component toward an opposite direction of gravity. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Additionally, the use of term herein, such as “unit” or “module”, to indicate a functional unit configured to process at least one function or operation may be implemented in and/or by processing circuitry, such as hardware, software, or in a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., unless expressly indicated otherwise. The processing circuitry may include electrical components such as at least one of transistors, resistors, capacitors, etc., and/or electronic circuits including said components. Also, connecting lines or connecting members illustrated in the drawings are intended to represent example functional relationships and/or physical or logical connections between the various elements. It should be noted that many alternative or additional functional relationships, physical connections or logical connections may be present in a practical device.

In addition, throughout the specification, unless explicitly described to the contrary, the word “comprise”, “include”, or “contain”, and variations such as “comprises”, “comprising”, “includes”, “including”, “contains”, or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-sectional view taken along a vertical direction is viewed from a side.

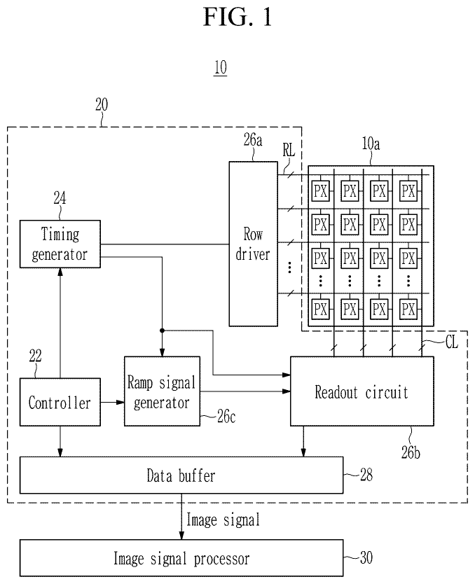

Hereinafter, referring to FIG. 1 to FIG. 10, an image sensor according to at least one example embodiment and a capacitor included in the same will be described in detail.

FIG. 1 is a block diagram schematically illustrating an image sensor 10 according to at least one example embodiment.

Referring to FIG. 1, an image sensor 10 according to at least one example embodiment may include a pixel array 10a, and a logic circuit 20 that controls the pixel array 10a. The logic circuit 20 is a circuit configured to control the pixel array 10a and, according to at least one example embodiments, includes, for example, a controller 22, a timing generator 24, a row driver 26a, a readout circuit 26b, a ramp signal generator 26c, and a data buffer 28. The image sensor 10 may further include (or be connected to) an image signal processor 30. In some example embodiments, the image signal processor 30 may be disposed outside the image sensor 10.

The image sensor 10 is configured to generate an image signal by converting light received from an outside into an electric signal, and the image signal generated by the image sensor 10 may be provided to the image signal processor 30.

The image sensor 10 may be mounted on an electronic device with an image or light sensing function. For example, the image sensor 10 may be mounted on electronic devices such as cameras, smartphones, wearable devices, internet of things (IoT) devices, home appliance devices, tablets, personal digital assistants (PDA), portable multimedia players (PMP), navigations, drones, advanced driver assistance systems (ADAS), and/or the like. In some example embodiments, the image sensor 10 may be mounted on an electronic device provided as a part of a vehicle, furniture, a manufacturing facility, a door, and/or various measuring devices.

The pixel array 10a may include a plurality of pixel regions PX, and a plurality of row lines RL and a plurality of column lines CL respectively connected to the plurality of pixel regions PX.

In at least one example embodiment, each pixel region PX may include at least one photodiode device. The photodiode device may detect incident light and convert the incident light into an electric signal, that is, a plurality of analog pixel signals, according to an amount of the incident light. The photodiode device may be a photodiode, a photo transistor, a photo gate, or a pinned photo diode (PPD). In some example embodiments, the photodiode device may be a single-photon avalanche diode (SPAD) applied to a 3D sensor pixel. A level of the analog pixel signal output from the photodiode device may be proportional to an amount of the light provided to each pixel region PX or an amount of charges output from the photodiode device.

The row line RL may extend in one direction and be connected to the plurality of pixel regions PX arranged in the one direction. For example, a control signal output from the row driver 26a to the row line RL may be transmitted to gates of transistors of the plurality of pixel regions PX that is connected to the row line RL. The column line CL may extend in a crossing direction that intersects the one direction and may be connected to the plurality of pixel regions PX arranged in the crossing direction. The plurality of pixel signals output from the plurality of pixel regions PX may be transmitted to the readout circuit 26b through the plurality of column lines CL.

In at least one example embodiment, one pixel region PX may form one unit pixel group. However, the example embodiments are not limited thereto, and other various modified embodiments are possible. In some example embodiments, the plurality of pixel regions PX may be grouped in a form of a plurality of columns and a plurality of rows to form one unit pixel group. That is, the plurality of pixel regions PX arranged in an extension direction of the row line RL and/or the plurality of pixel regions PX arranged in an extension direction of the column line CL may form one unit pixel group. For example, one unit pixel group may include a plurality of pixels arranged in a form of two columns and/or two rows, and one unit pixel group may output one analog pixel signal.

In at least one example embodiment, each pixel region PX may include a pixel circuit that processes the charge generated by the photodiode device and outputs the electric signal. The pixel circuit may include a transfer transistor, a reset transistor, a selection transistor, a source follower transistor, or the like. The example embodiments are not limited thereto and the pixel circuit may have any of various structures.

The controller 22 may be configured to generally control the timing generator 24, the row driver 26a, the readout circuit 26b, the ramp signal generator 26c, and/or the data buffer 28 included in the image sensor 10. For example, the controller 22 may control an operation timing by using a control signal. In at least one example embodiment, the controller 22 may receive a mode signal indicating an imaging mode from an application processor and generally control the image sensor 10 based on the received mode signal.

The timing generator 24 may be configured to generate a signal that serves as a reference for the operation timing of the image sensor 10. The timing generator 24 may provide a control signal that controls the timing of the row driver 26a, the readout circuit 26b, and the ramp signal generator 26c.

The row driver 26a may be configured to generate a control signal to drive the pixel array 10a in response to the control signal of the timing generator 24, and may provide the control signal to the plurality of pixel regions PX of the pixel array 10a through the plurality of row lines RL. For example, the row driver 26a may generate a transfer signal that controls the transfer transistor, a reset control signal that controls the reset transistor, and a selection control signal that controls the selection transistor, and provide the transfer signal, the reset control signal, and the selection signal to the pixel array 10a.

The readout circuit 26b may be configured to convert a pixel signal (or an electric signal) output through the corresponding column line CL into a pixel value representing the amount of light. The ramp signal generator 26c may generate a reference signal or a ramp signal and transmit the reference signal or the ramp signal to the readout circuit 26b. For example, the readout circuit 26b may convert the pixel signal to the pixel value by comparing the ramp signal and the pixel signal. The pixel value may be an image data with a plurality of bits.

The data buffer 28 may be configured to store the pixel value of the pixel region PX transmitted from the readout circuit 26b and may output the stored pixel value in response to a signal from the controller 22.

The image signal processor 30 may be configured to perform image-signal processing on the image signal received from the data buffer 28. For example, the image signal processor 30 may receive the plurality of image signals from the data buffer 28 and generate one image by combining the received image signals.

The example embodiments are not limited to the above descriptions, and a structure, a type, or the like of the image sensor 10 may be variously modified.

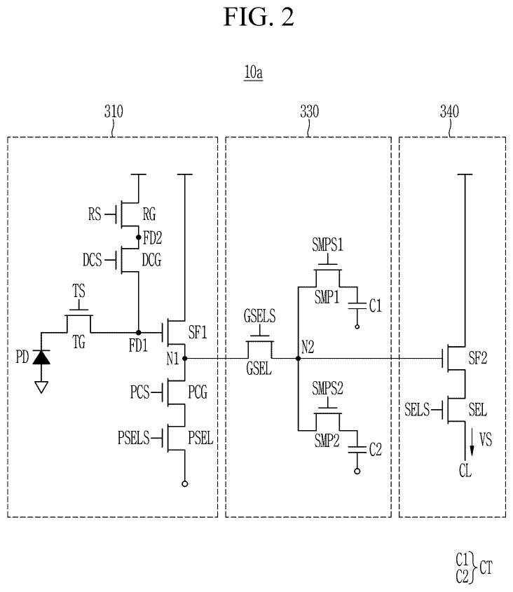

FIG. 2 is a circuit diagram of the pixel array 10a that is included in the image sensor 10 illustrated in FIG. 1.

Referring to FIG. 2, in at least one example embodiment, an image sensor 10 may have a global shutter structure configured to perform a global shutter operation. For example, the image sensor 10 may include a photoelectric charge generation circuit 310, a sampling circuit 330, and a pixel signal circuit 340.

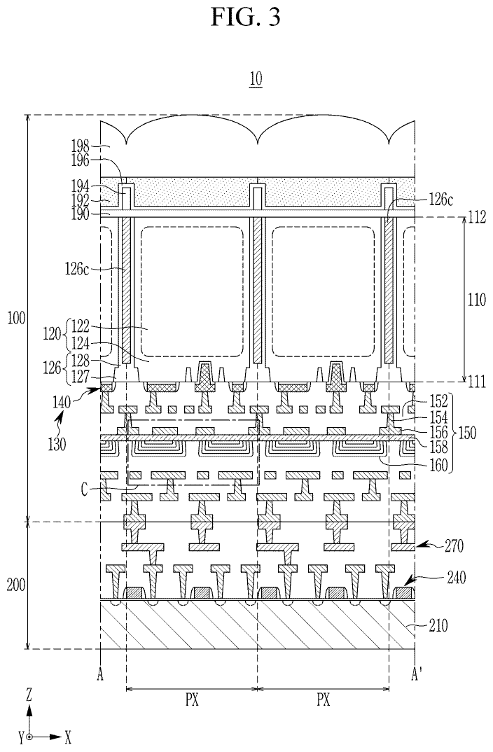

The photoelectric charge generation circuit 310 may include a photodiode PD, a transfer transistor TG, a reset transistor RG, a first source follower transistor SF1, and may further include a dual conversion gain transistor DCG, a precharge transistor PCG, and a precharge selection transistor PSEL. The photoelectric charge generation circuit 310 may transfer photoelectric charges generated by the photodiode PD to the sampling circuit 330. The photodiode PD illustrated in FIG. 2 may be or correspond to a photoreceptive portion of a photodiode (a first conductive type region 122) and/or a photodiode region 120 illustrated in FIG. 3.

The transfer transistor TG may be connected between the photodiode PD and a first floating diffusion node FD1. In response to a transfer control signal TS applied to a gate of the transfer transistor TG, the transfer transistor TG may transfer charges generated in the photodiode PD to the first floating diffusion node FD1.

The dual conversion gain transistor DCG may be connected between the first floating diffusion node FD1 and the reset transistor RG. The dual conversion gain transistor DCG may be controlled by a gain control signal DCS. The dual conversion gain transistor DCG may be a transistor configured to reduce a conversion gain, which is a rate at which charges are converted into a voltage, by controlling capacitance. According to turn-on or turn-off of the dual conversion gain transistor DCG, the image sensor 10 may operate in various modes.

The reset transistor RG may be connected between a power voltage line that supplies a power supply voltage and a second floating diffusion node FD2. When a reset control signal RS is applied to the reset transistor RG, the charges that are accumulated in the second floating diffusion node FD2 may be reset. When the reset control signal RS is applied to the reset transistor RG and the dual conversion gain transistor GCS is turned on, the charges accumulated in the first floating diffusion node FD1 may be reset.

In FIG. 2, it is illustrated as an example that dual conversion gain transistor DCG is connected between the first floating diffusion node FD1 and the second floating diffusion node FD2. In some example embodiments, the dual conversion gain transistor DCG may include a plurality of dual conversion transistors. For example, the dual conversion gain transistor DCG may include a first dual conversion gain transistor connected between the first floating diffusion node FD1 and a third floating diffusion node, and a second dual conversion gain transistor connected between the third floating diffusion node and the second floating diffusion node FD2. However, the example embodiments are not limited thereto. In some example embodiments, the pixel array 10a may not include the dual conversion gain transistor DCG. When the dual conversion gain transistor DCG is not included, an end of the reset transistor RG may be directly connected to the first floating diffusion node FD1.

A gate of the first source follower transistor SF1 may be connected to the first floating diffusion node FD1. The first source follower transistor SF1 may be a source follower buffer amplifier. The first source follower transistor SF1 may perform buffering of a signal according to an amount of charges accumulated in the first floating diffusion node FD1. The first source follower transistor SF1 may amplify a potential change at the first floating diffusion node FD1 and output the amplified result to a first output node N1.

A precharge transistor PCG may precharge the first output node N1 according to a precharge control signal PCS. The precharge selection transistor PSEL may reset the first output node N1 according to a precharge selection control signal PSELS.

The sampling circuit 330 may include a global shutter selection transistor GSEL, a sampling transistor SMP1 or SMP2, and a capacitor CT. In at least one example embodiment, the sampling transistor SMP1 or SMP2 may include a plurality of sampling transistors (e.g., a first sampling transistor SMP1 and a second sampling transistor SMP2), and the capacitor CT may include a plurality of capacitors (e.g., a first capacitor C1 and a second capacitor C2).

The global shutter selection transistor GSEL may be connected between the first output node N1 and the second output node N2, and may be controlled by a global shutter selection control signal GSELS.

The first sampling transistor SMP1 may be connected to the second output node N2 and the first capacitor C1, and may be controlled by a first sampling control signal SMPS1. When the first sampling transistor SMP1 is turned on, charges are accumulated in the first capacitor C1 and sampling of an electrical signal of the second output node N2 may be performed. The second sampling transistor SMP2 may be connected to the second output node N2 and the second capacitor C2, and may be controlled by a second sampling control signal SMPS2. When the second sampling transistor SMP2 is turned on, charges are accumulated in the second capacitor C2 and sampling of an electrical signal of the second output node N2 may be performed.

For example, charges that correspond to the buffered signal based on an amount of charges generated or reset in a plurality of sections included in the global shutter operation may be accumulated in the capacitor CT. That is, the capacitor CT may be (or correspond to) a memory device configured to perform the global shutter operation. The capacitor CT illustrated in FIG. 2 may be or correspond to a capacitor illustrated in FIG. 3.

The pixel signal circuit 340 may include a second source follower transistor SF2 and a selection transistor SEL.

A gate of the second source follower transistor SF2 may be connected to the second output node N2. The second source follower transistor SF2 may be a source follower buffer amplifier. The second source follower transistor SF2 may perform buffering of a signal according to an amount of charges accumulated in the second output node N2. The second source follower transistor SF2 may amplify a potential change at the second output node N2 and output the amplified result. In respond to a selection control signal SELS, the selection transistor SEL may output a pixel signal VS to the column line CL.

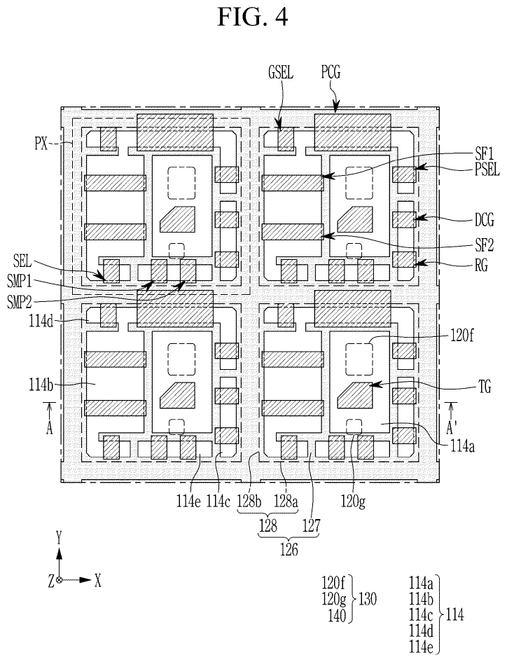

Referring to FIG. 3 and FIG. 4, an image sensor 10 according to at least one example embodiment will be described in more detail.

FIG. 3 is a partial cross-sectional view illustrating an image sensor 10 according to at least one example embodiment. FIG. 4 is a rear plan view schematically illustrating the image sensor 10 illustrated in FIG. 3. FIG. 3 is a cross-sectional view taken along a line A-A′ in FIG. 4, and FIG. 4 illustrates an isolation pattern 126, an active region 114, and a pixel circuit 130 based on a first surface 111 of a substrate 110. For a clear understanding, a gate electrode of a transistor 140 is mainly illustrated for the transistor 140 in FIG. 4.

Referring to FIG. 3 and FIG. 4, in at least one example embodiment, an image sensor 10 may include a substrate 110, a plurality of pixel regions PX, and a wiring portion 150. The substrate 110 may have a first surface 111 and a second surface 112 that are opposite to each other. Each of the plurality of pixel regions PX may include a photodiode region 120 (e.g., a photodiode) in the substrate 110 and a pixel circuit 130 at (e.g., in and/or on) the first surface 111 of the substrate 110. The wiring portion 150 may be on the first surface 111 of the substrate 110 and may be electrically connected to the pixel circuit 130. The wiring portion 150 may include a capacitor 160.

In at least one example embodiment, the substrate 110 may include a semiconductor substrate that includes or is formed of a semiconductor material. For example, the substrate 110 may include a bulk substrate that includes (and/or is formed of) a semiconductor material, a substrate that includes a bulk substrate and an epitaxial layer on the bulk substrate, a semiconductor-on-insulator, and/or the like. In at least some example embodiments, the semiconductor material included in the substrate 110 may include a second conductivity type dopant to have a second conductivity type (e.g., a p-type or an n-type) that is opposite to a conductivity type of a first conductivity type region 122.

The semiconductor material included in the substrate 110 may include or be formed of at least one of an elemental semiconductor (e.g., a group IV semiconductor) and/or a compound (e.g., at least one of a group III-V compound semiconductor, a group II-VI compound semiconductor, etc.). For example, the semiconductor material that is included in the substrate 110 may include or be formed of at least one of Si, Ge, SiGe, SiC, GaAs, InAs, GaP, InP, InSb, InGaAs, ZnTe, and/or CdS. For example, the bulk substrate may be a single-crystalline or polycrystalline semiconductor substrate and may include or be formed of at least one of Si, Ge, and/or SiGe. In some example embodiments, the semiconductor-on-insulator may be at least one of a silicon-on-insulator (SOI), a germanium-on-insulator (GOI), and/or a silicon-germanium-on- insulator (SGOI).

For example, the plurality of pixel regions PX may include a first pixel region, a second pixel region, a third pixel region, and a fourth pixel region. The first pixel region and the second pixel region may be adjacent to each other in a first direction (an X-axis direction in the drawings). The third pixel region and the fourth pixel region may be adjacent to the first pixel region and the second pixel region, respectively, in a second direction (a Y-axis direction in the drawings) that intersects the first direction (the X-axis direction in the drawings). In at least one example embodiment, each pixel region PX may be a unit pixel configured to output one pixel signal. However, the example embodiments are not limited thereto. In some example embodiments, a plurality of pixel regions PX may be a unit pixel configured to output one pixel signal, or a portion of each pixel region PX may be a unit pixel configured to output one pixel signal.

The photodiode region 120 in the substrate 110 may be configured to convert light incident from an outside to an electrical signal. In FIG. 3, it is illustrated as an example that one photodiode or one photodiode region 120 is disposed in each pixel region PX. However, the example embodiments are not limited thereto. In some example embodiments, a plurality of photodiodes or a plurality of photodiode regions 120 may be disposed in each pixel region PX.

For example, the photodiode region 120 may include a first conductivity type region 122 and a second conductivity type region 124. The first conductivity type region 122 may include a first conductivity type dopant to have a first conductivity type (e.g., an n-type or a p-type) that is opposite to a conductive type of the substrate 110. The first conductivity type region 122 may also be referred to as a photoelectric conversion element, and may be provided as (or a component of) the photodiode PD. The second conductivity type region 124 may include a second conductivity type dopant to have a second conductivity type (e.g., a p-type or an n-type) that is opposite to the first conductive type. The first and second conductivity type regions 122 and 124 may be referred to as being included in a photoelectric conversion element region. The first conductivity type region 122 may be formed by doping the first conductivity type dopant to a portion of the substrate 110. The second conductivity type region 124 may be formed by doping the second conductivity type dopant to a portion of the substrate 110 that is adjacent to the first surface 111 of the substrate 110. In some example embodiments, the second conductivity type region 124 may be formed of a portion of the substrate 110 where the first conductivity type region 122 is not positioned. The photodiode or the photodiode region 120 may be constituted by a p-n junction of the first conductivity type region 122 and the second conductivity type region 124. The photodiode region 120 may generate and accumulate charges in proportion to an amount of light provided to each pixel region PX. The first conductivity type region 122 may be referred to as a photodiode.

The isolation pattern 126 passing through at least a portion of the substrate 110 may define a region where an active region 114 and/or the photodiode region 120 is disposed. At least a portion of the isolation pattern 126 (e.g., at least a portion of a second isolation pattern 128) may be disposed to correspond to a boundary of each pixel region PX. The isolation pattern 126 may be referred to as a photodiode (PD) isolation pattern.

In at least one example embodiment, in a cross-sectional view, the isolation pattern 126 may pass through or penetrate at least a portion of the substrate 110 in a thickness direction (a Z-axis direction in the drawings). In at least one example embodiment, the isolation pattern 126 may be formed by forming a shallow trench isolation pattern (a shallow trench isolation, STI) and a deep trench isolation pattern (a deep trench isolation, DTI). For example, the isolation pattern 126 may include a front deep trench isolation (FDTI) pattern that includes a portion adjacent to the first surface 111 of the substrate 110 and/or a back deep trench isolation (BDTI) pattern that includes a portion adjacent to the second surface 112 of the substrate 110. In some example embodiments, a doping region or a separation doping region may be disposed in a portion where the isolation pattern 126 is disposed in a plan view.

In at least one example embodiment, the isolation pattern 126 may include a first isolation pattern 127 and a second isolation pattern 128. The first isolation pattern 127 may be adjacent to the first surface 111 of the substrate 110. The second isolation pattern 128 may be connected to the first isolation pattern 127 and extend in the thickness direction (the Z-axis direction in the drawings).

The first isolation pattern 127 may define the active region 114 in a portion adjacent to the first surface 111 of the substrate 110 in a cross-sectional view. For example, the first isolation pattern 127 may be disposed in a portion other than the active region 114.

The second isolation pattern 128, farther away from the first surface 111 of the substrate 110 than the first isolation pattern 127, may define a region where the photodiode region 120 is disposed. For example, the second isolation pattern 128 may include a first extension portion 128a and a second extension portion 128b. The first extension portion 128a may extend in the first direction (the X-axis direction in the drawings), and the second extension portion 128b may extend in the second direction (the Y-axis direction in the drawings). The first extension portion 128a and the second extension portion 128b may be disposed to correspond to a boundary of each pixel region PX. For example, in a plan view, the second isolation pattern 128 may have a lattice shape to correspond to the boundary of each pixel region PX. Thereby, in a plan view, a pair of first extension portions 128a may extend in the first direction at opposite sides of each pixel region PX in the second direction, and a pair of second extension portions 128b may extend in the second direction at opposite sides of each pixel region PX in the first direction. In a plan view, the photodiode region 120 in each pixel region PX may be surrounded by a pair of first extension portions 128a and a pair of second extension portions 128b.

The isolation pattern 126 may include an insulating material layer. For example, the insulating material layer of the isolation pattern 126 may include (or be formed of) at least one of silicon oxide, silicon nitride, and/or silicon oxynitride, and/or may include a single layer or a plurality of layers. However, the example embodiments are not limited thereto. A material of the insulating material layer of the isolation pattern 126 may be variously modified. For example, the first isolation pattern 127 adjacent to the first surface 111 of the substrate 110 may include a same material or a uniform material in the entirety of the first isolation pattern. In some example embodiments, the first isolation pattern 127 adjacent to the first surface 111 of the substrate 110 may include portions including different materials. However, the example embodiments are not limited thereto.

In at least one example embodiment, the isolation pattern 126 may further include a conductive layer 126c. For example, the conductive layer 126c of the isolation pattern 126 may be disposed in the insulating material layer of the isolation pattern 126.

The conductive layer 126c of the isolation pattern 126 may include (or be formed) of a semiconductor material (e.g., silicon). A dark current may be improved through a hole accumulation induced by a negative voltage applied to the conductive layer 126c of the isolation pattern 126. However, the example embodiments are not limited thereto. The negative voltage may not be applied to the conductive layer 126c of the isolation pattern 126, or the isolation pattern 126 may not include the conductive layer 126c.

A sidewall doping region may be disposed at a portion of the substrate 110 that is adjacent to the isolation pattern 126 (e.g., the second isolation pattern 128). Sidewall doping regions may be disposed at portions adjacent to both sidewalls of the isolation pattern 126 (e.g., the second isolation pattern 128), respectively. The sidewall doping region may improve the dark current, together with the conductive layer 126c of the isolation pattern 126. The sidewall doping region may have the second conductivity type (the p-type or the n-type) that is same as a conductivity type of the substrate 110. For example, the sidewall doping region may have the p-type, and/or may include, e.g., boron, aluminum, gallium, indium, and/or the like as a p-type dopant.

In FIG. 3, it is illustrated as an example that a surface of the isolation pattern 126 adjacent to the first surface 111 of the substrate 110 is disposed on a same plane as the first surface 111 of the substrate 110. However, the example embodiments are not limited thereto. In some example embodiments, the first surface 111 of the substrate 110 and the surface of the isolation pattern 126 may be disposed on different planes.

The pixel circuit 130 adjacent to the first surface 111 of the substrate 110 may include a plurality of transistors 140 and a doping region. The plurality of transistors 140 and the doping region may be disposed in the active region 114 defined by the first isolation pattern 127 in a portion adjacent to the first surface 111 of the substrate 110. In some example embodiments, the pixel circuit 130 may further include a connection wiring electrically connected the transistor 140 and/or the doping region. In some example embodiments, at least one doping region may be disposed to be adjacent to the second surface 112 of the substrate 110 in a cross-sectional view at a portion where the isolation pattern 126 is disposed in a plan view.

For example, the plurality of transistors 140 may include a transfer transistor TG, a reset transistor RG, a dual conversion gain transistor DCG, a precharge transistor PCG, a precharge selection transistor PSEL, a global shutter selection transistor GSEL, a sampling transistors SMP1 and SMP2, a selection transistor SEL, a first source follower transistor SF1, and/or a second source follower transistor SF2. However, the example embodiments are not limited thereto. In some example embodiments, the plurality of transistors 140 may include more or fewer transistors.

The transfer transistor TG may have a vertical transfer gate (VTG) structure. For example, the transfer transistor TG may include a vertical transfer gate electrode and a gate dielectric layer. The vertical transfer gate electrode may extend in the thickness direction (the Z-axis direction in the drawings) of the image sensor 10, and the gate dielectric layer may be disposed between the substrate 110 and the vertical transfer gate electrode. The reset transistor RG, the dual conversion gain transistor DCG, the precharge transistor PCG, the precharge selection transistor PSEL, the global shutter selection transistor GSEL, the sampling transistors SMP1 and SMP2, the selection transistor SEL, the first source follower transistor SF1, and/or the second source follower transistor SF2 may have a structure (e.g., a planar structure) different from a structure of the transfer transistor TG. For example, the reset transistor RG, the dual conversion gain transistor DCG, the precharge transistor PCG, the precharge selection transistor PSEL, the global shutter selection transistor GSEL, the sampling transistors SMP1 and SMP2, the selection transistor SEL, the first source follower transistor SF1, and/or the second source follower transistor SF2 may include a gate dielectric layer and a gate electrode, spacers, or so on. The gate dielectric layer and the gate electrode may extend in a horizontal direction on the first surface 111 of the substrate 110, and the spacers may be disposed at opposite sides of the gate electrode.

In FIG. 3, it is illustrated as an example that transistor 140 includes a portion on the first surface 111 of the substrate 110, but the example embodiments are not limited thereto. The transistor 140 and/or at least a portion of a connection wiring electrically connected to the transistor 140 may have a buried structure buried in the substrate 110.

For example, the doping region may include a floating diffusion region 120f and/or a ground region 120g. The floating diffusion region 120f may have a first conductivity type opposite to the second conductivity type of the substrate 110, and charges generated by the photodiode region 120 may be accumulated in the floating diffusion region 120f. The ground region 120g may have a second conductivity type same as a conductivity type of the substrate 110, and may have a doping concentration higher than a doping concentration of the substrate 110 or a second conductivity type region 124. A ground voltage may be applied to the ground region 120g. However, the example embodiments are not limited thereto. In some example embodiments, the floating diffusion region 120f and/or the ground region 120g may be omitted. In some example embodiments, a doping region other than the floating diffusion region 120f and/or the ground region 120g may be further included.

In at least one example embodiment, a first active region 114a may be disposed in a central portion of the pixel region PX. In the first active region 114a, the transfer transistor TG may be disposed, and the floating diffusion region 120f and/or the ground region 120g may be disposed.

A second active region 114b may be disposed at a first side (a left side in FIG. 4) of the pixel region PX, and the first source follower transistor SF1, the second source follower transistor SF2, and the selection transistor SEL may be disposed in the second active region 114b.

A third active region 114c may be disposed in a portion (a lower portion in FIG. 4) of a second side (a right side in FIG. 4) of the pixel region PX opposite to the first side of the pixel region PX, and the dual conversion gain transistor DCG and the reset transistor RG may be disposed in the third active region 114c.

A fourth active region 114d may be disposed at a third side (an upper side in FIG. 4) of the pixel region PX and another portion (an upper portion in FIG. 4) of the second side (the right side in FIG. 4) of the pixel region PX. The fourth active region 114d may be connected to the second active region 114b. In the fourth active region 114d, the precharge transistor PCG, the precharge selection transistor PSEL, and the global shutter selection transistor GSEL may be disposed.

A fifth active region 114e may be disposed at a portion of a fourth side (a lower side in FIG. 4) of the pixel region PX opposite to the third side of the pixel region PX. The fifth active region 114e may be disposed between the second active region 114b and the third active region 114c at the fourth side of the pixel region PX. The sampling transistors SMP1 and SMP2 may be disposed in the fifth active region 114e.

As in the above, in at least one example embodiment, each pixel region PX may include the plurality of transistors 140 configured to operate the image sensor 10. In FIG. 4, it is illustrated as an example that each pixel region PX includes a plurality of transistors 140 configured to operate the pixel array. Thereby, each pixel region PX may be a unit pixel configured to output one pixel signal. However, the example embodiments are not limited thereto. The example embodiments are not limited to an arrangement of the active region 114 and an arrangement of the plurality of transistors 140 illustrated in FIG. 4.

The wiring portion 150 electrically connected to the pixel circuit 130 may be disposed on the first surface 111 of the substrate 110. That is, the wiring portion 150 may be disposed to be adjacent to the first surface 111 of the substrate 110, which is opposite to the second surface 112 of the substrate 110 to which the light is incident, and thus, the wiring portion 150 may not be disposed in a path of the light incident to the image sensor 10. Thereby, light interference caused by the wiring portion 150 may be minimized.

The wiring portion 150 may include a plurality of wiring layers 156 that are electrically connected to the pixel circuit 130 through a contact via 154 that passes through or penetrates an interlayer insulation layer 152, and a capacitor 160. The wiring portion 150 may further include a capping layer 158 between the wiring layer 156 and the capacitor 160 and/or between the interlayer insulation layer 152 and the capacitor 160.

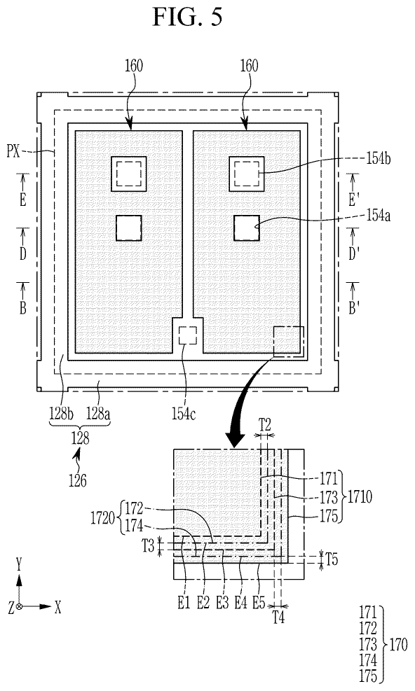

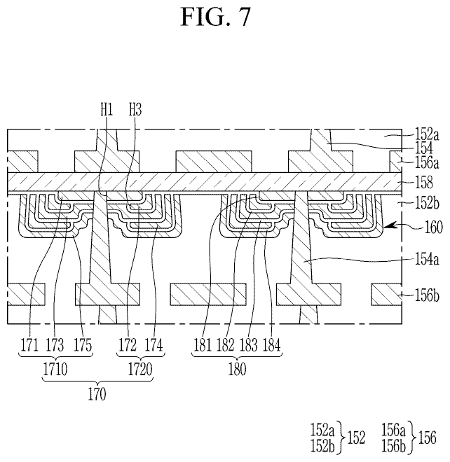

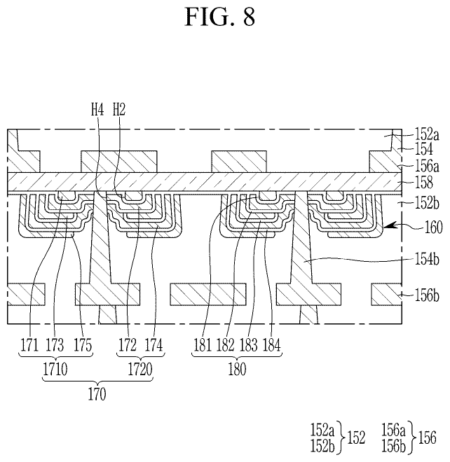

The contact via 154, the wiring layer 156, and the capacitor 160 of the wiring portion 150 may be connected to form a desired circuit. The contact via 154 may be formed in the same process as the wiring layer 156, or may be formed in a separate process from the wiring layer 156. In the thickness direction (the Z-axis direction in the drawings) of the image sensor 10, the capacitor 160 may be disposed on the capping layer 158 between the plurality of wiring layers 156, and may be electrically connected to the contact via 154 (e.g., a capacitor contact via 154a or 154b (refer to FIG. 7 and FIG. 8)). The capacitor 160 and the capping layer 158 will be described later in more detail with reference to FIG. 5 to FIG. 10.

The interlayer insulation layer 152 of the wiring portion 150 may include an insulating material. For example, the interlayer insulation layer 152 of the wiring portion 150 may include or be formed of silicon oxide, silicon nitride, silicon oxynitride, and/or a low dielectric constant material. The low dielectric constant material may have a lower dielectric constant than silicon oxide.

The contact via 154 and/or the wiring layer 156 of the wiring portion 150 may include or be formed of a conductive material, such as at least one of metal, metal alloy, metal nitride, metal silicide (metal silicide), and/or a doped semiconductor material. The metal or the metal alloy may include or be formed of at least one of titanium, tungsten, molybdenum, tantalum, aluminum, copper, nickel, ruthenium, and/or cobalt, and the metal nitride may include or be formed of at least one of titanium nitride, tungsten nitride, molybdenum nitride, and/or tantalum nitride. The contact via 154 and/or the wiring layer 156 of the wiring portion 150 may further include metal oxide or metal oxynitride in which the above material is oxidized. The contact via 154 and/or the wiring layer 156 of the wiring portion 150 may include a single layer or a plurality of layers.

However, the example embodiments are not limited thereto. In some example embodiments, the interlayer insulation layer 152 of the wiring portion 150 may include one or more insulating materials, and the contact via 154 and/or the wiring layer 156 of the wiring portion 150 may include one or more conductive materials.

A light receiving portion (e.g., a horizontal insulation layer 190, a color filter 192, a grid 194, a protection layer 196, and/or a micro lens 198) may be disposed on the second surface 112 of the substrate 110.

More particularly, the horizontal insulation layer 190 may be disposed on the second surface 112 of the substrate 110. The horizontal insulation layer 190 may be disposed to cover the second surface 112 of the substrate 110 and the isolation pattern 126. The horizontal insulation layer 190 may act as a kind of a planarization layer configured to planarize a surface so that the color filter 192, the grid 194, the micro lens 198, or the like disposed on the horizontal insulation layer 190 is stably formed.

The horizontal insulation layer 190 may include any of various insulating materials. For example, the horizontal insulation layer 190 may include or be formed of oxide, nitride, oxynitride, and/or fluoride including at least one of hafnium, zirconium, aluminum, tantalum, titanium, yttrium, cerium, lanthanum, neodymium, praseodymium, ytterbium, and/or silicon. For example, the horizontal insulation layer 190 may act as an anti-reflection layer, but the example embodiments are not limited thereto.

In at least one example embodiment, the horizontal insulation layer 190 may include a plurality of layers including different materials and having different thicknesses. For example, in the horizontal insulation layer 190, a first horizontal insulation layer adjacent to the second surface 112 of the substrate 110 may be a fixed charge layer having a negative fixed charge. Thereby, the dark current may be improved by a hole accumulation at a periphery of the fixed charge layer. In at least one example embodiment, the first horizontal insulation layer may include (or be formed of) metal oxide or metal fluoride including at least one of hafnium, zirconium, aluminum, tantalum, titanium, and/or yttrium. For example, the horizontal insulation layer 190 or the anti-reflection layer may include a first horizontal insulation layer including hafnium oxide, a second horizontal insulation layer including silicon oxide or silicon nitride, and a third horizontal insulation layer including hafnium oxide.

However, the example embodiments are not limited to thereto, and a number, a thickness, and/or the like of layers included in the horizontal insulation layer 190 may be variously modified. In some example embodiments, a structure configured to reflect light may be disposed at the second surface 112 of the substrate 110. For example, a nano-porous structure that has a nanometer-level size may be formed at the second surface 112 of the substrate 110 by using laser or etching, thereby reflecting the light. The nanometer-level size may refer to a size (e.g., an average width, an average diameter, and/or an average pitch) of less than 1 micrometers (um). Thereby, the anti-reflection layer may be omitted in the horizontal insulation layer 190 and a manufacturing process may be simplified. However, the example embodiments are not limited thereto. In some example embodiments, when the structure configured to reflect the light is disposed at the second surface 112 of the substrate 110, the horizontal insulation layer 190 may include the anti-reflection layer.

The grid 194 may be disposed on the horizontal insulation layer 190. In at least one example embodiment, the grid 194 may surround at least a portion of the color filter 192. For example, the grid 194 may have a lattice structure that is same as or similar to the lattice structure of the isolation pattern 126, but the example embodiments are not limited thereto. The grid 194 may be referred to as a fence pattern or a filter separator.

The grid 194 may protect against light that is incident obliquely into one color filter 192 in one of the plurality of pixel regions PX entering another color filter 192 in adjacent pixel region PX. Accordingly, a crosstalk between the plurality of pixel regions PX may be prevented and/or mitigated.

In at least one example embodiment, the grid 194 may include or be formed of a material having a refractive index smaller than a refractive index of the color filter 192 or silicon oxide, and/or a material having a refractive index of about 1.0 to about 1.4. When the grid 194 includes a material with a small refractive index in the above, the light incident on the grid 194 may be totally reflected and directed toward an inside of the pixel region PX.

For example, the grid 194 may include or be formed of polymethyl methacrylate (PMMA), silicon acrylate, cellulose acetate butyrate (CAB), silica, fluorine-silicon acrylate (FSA), and/or the like. For example, the grid 194 may include or be formed of a polymer material in which silica particles are dispersed. However, the example embodiments are not limited to thereto, and the grid 194 may include a material different from the above listed materials.

The color filter 192 may be disposed on the horizontal insulation layer 190. The plurality of color filters 192 may be separated from each other by the grid 194. A plurality of color filters 192 may include, for example, a green filter, a blue filter, and a red filter. In some example embodiments, the plurality of color filters 192 may include a cyan filter, a magenta filter, a yellow filter, an infrared filter to allow infrared light to pass through, and/or the like. In some example embodiments, a pixel region PX where all visible light is incident may be provided.

The protection layer 196 may be disposed on the color filter 192 and/or the grid 194. In FIG. 3, it is illustrated as an example that the protection layer 196 is disposed between the grid 194 and the color filter 192 on the grid 194. The protection layer 196 may include or be formed of any of various materials such as an organic material, silicon oxide, silicon oxynitride, aluminum oxide, and/or the like. However, the example embodiments are not limited to a material of the protection layer 196. The protection layer 196 may be omitted, and/or the protection layer 196 may be disposed on the color filter 192 and the grid 194.

The micro lens 198 that is disposed on the color filter 192 and/or the protection layer 196 may include or be formed of a portion having a convex shape to converge or concentrate light incident to the pixel region PX. The micro lens 198 may include or be formed of any or various resin materials, for example, a styrene-based resin, an acryl-based resin, a styrene-acryl copolymer resin, a siloxane-based resin, and/or the like.

However, the example embodiments are not limited to thereto, and a shape, a material, and/or the like of the micro lens 198 may be variously modified. In some example embodiments, a meta lens may be included instead of the micro lens 198. The meta lens may include a nano structure of a nano rod or a nano pillar that has a nanometer-level size. In the meta lens, by a meta surface including meta atoms that are smaller than a wavelength of light uniformly or periodically, a direction of incident light may be changed so that the light reach a specific point. Thereby, the meta lens may act as a lens. The meta lens or the nano structure may include or be formed of Si, SiN, GaN, TiO₂, and/or the like.

In FIG. 3, it is illustrated as an example that one micro lens 198 corresponds to each pixel region PX. However, the example embodiments are not limited thereto. In some example embodiments, one micro lens 198 may correspond to a plurality of pixel regions PX. In some example embodiments, one micro lens 198 may correspond to a portion of the pixel region PX. In some example embodiments, a protective layer or the like may be disposed on an outer surface of the micro lens 198.

In FIG. 3, it is illustrated as an example that the grid 194 corresponds to each pixel region PX. However, the example embodiments are not limited thereto, and other various modified embodiments are possible.

In at least one example embodiment, in a plan view, a relative position between the pixel region PX and the color filter 192 and/or a relative position between the pixel region PX and the micro lens 198 may be different from each other in a central portion of the image sensor 10 and in an edge portion of the image sensor 10. That is, in a plan view, an area (e.g. a planar area) of the color filter 192 that overlaps the pixel region PX and/or an area (e.g. a planar area) of the micro lens 198 that overlaps the pixel region PX may be smaller in the edge region of the image sensor 10 than in the central region of the image sensor 10. For example, an area (e.g. a planar area) of the color filter 192 that overlaps the pixel region PX and/or an area (e.g. a planar area) of the micro lens 198 that overlaps the pixel region PX may decrease from the central region of the image sensor 10 to the edge region of the image sensor 10.

By adjusting the relative position between the pixel region PX and the color filter 192 and/or the relative position between the pixel region PX and the micro lens 198, an amount of the light that reaches the photodiode region 120 in the pixel region PX may be increased and/or maximized. For example, the micro lens 198, the color filter 192, and the photodiode region 120 in the pixel region PX may be disposed to be overlapped in a direction where light passes. Since the light is incident obliquely in the edge region of the image sensor 10, the relative position between the pixel region PX and the color filter 192 and/or the relative position between the pixel region PX and the micro lens 198 may be adjusted so that the light that is incident obliquely reaches the photodiode region 120 in the pixel region PX to a large amount.

An additional wiring portion 200 may be further disposed on a photodiode substrate 100 including the substrate 110, the pixel region PX, the wiring portion 150, and the light receiving portion. For example, the additional wiring portion 200 may be further disposed on the wiring portion 150. The additional wiring portion 200 may include a substrate 210, and a logic circuit portion, a power supply portion, and/or the like. The logic circuit portion, the power supply portion, etc. may each include a transistor 240, a wiring 270, and/or the like. The image sensor 10 may have a multi-layered stacking structure that includes the photodiode substrate 100 and the additional wiring portion 200. When the additional wiring portion 200 is included as in the above, congestion of wirings, circuit elements, and/or the like that is included in the pixel circuit 130, the wiring portion 150, and the additional wiring portion 200 may be reduced. Thereby, an integration degree and performance of the image sensor 10 may be enhanced.

In FIG. 3, it is illustrated as an example that the image sensor 10 includes the photodiode substrate 100 and the additional wiring portion 200 to have a two-layered stacking structure. That is, the plurality of transistors 140 are included in the pixel circuit 130, and the capacitor 160 of a memory device may be included in the photodiode substrate 100. Thereby, an additional portion (e.g., a middle substrate or a middle plate) for forming at least a part of the plurality of transistors 140 may be not needed. Accordingly, a structure of the image sensor 10 may be simplified, and a number of processes and process cost may be reduced.

However, the example embodiments are not limited thereto. In some example embodiments, a member or an element in the addition wiring portion 200 may be included in the wiring portion 150 at or on the substrate 110 so that the image sensor 10 is formed of a single portion. In some example embodiments, the image sensor 10 may include the photodiode substrate 100 and two or more additional wiring portions to have a stacking structure having three or more layers. In these instances, the capacitor 160 may be disposed in the photodiode substrate 100, but the example embodiments are not limited thereto.

In the image sensor 10 according to at least one example embodiment, the light incident from the outside may be converged or concentrated by the micro lens 198 and be incident to the photodiode region 120 through the color filter 192. The light incident to the photodiode region 120 may be converted into an electric signal according to an amount of the light. For example, the photodiode region 120 may be configured to have a threshold potential corresponding to an amount of light and/or the magnitude of the electric signal may be based on the amount (e.g., duration and/or intensity) of the light.

The image sensor 10 according to at least one example embodiment may have a global shutter structure configured to perform a global shutter operation. Thus, the image sensor 10 may include a memory device (e.g., the capacitor 160) that is electrically connected to the pixel circuit 130. Signals in the entirety of pixel regions PX may be simultaneously stored by the memory device and thus a moving image may be implemented without distortion. However, the example embodiments are not limited thereto. In some example embodiments, the image sensor 10 may perform any of various operations.

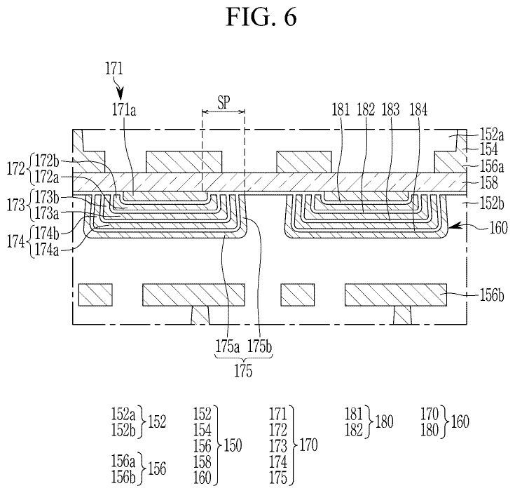

Referring to FIG. 5 and FIG. 6, the capacitor 160 in each pixel region PX will be described in detail.

FIG. 5 is a rear plan view schematically illustrating the capacitor 160 in each pixel region PX of the image sensor 10 illustrated in FIG. 4. FIG. 6 is a partial cross-sectional view taken along a line B-B′ in FIG. 5. FIG. 6 illustrates a portion corresponding to a portion C in FIG. 3.

For a clear understanding and simple illustration, in FIG. 5, the second isolation pattern 128 and an electrode (e.g., a fifth electrode 175) of the capacitor 160 are mainly illustrated, and positions of capacitor contact vias 154a and 154b and a power contact via 154c electrically connected to the capacitor 160 are illustrated as a dotted line.

Referring to FIG. 5 and FIG. 6, in at least one example embodiment, the capacitor 160 may be disposed between two wiring layers 156 (e.g., a first wiring layer 156a and a second wiring layer 156b) included in the wiring portion 150 to be electrically insulated from the two wiring layers 156 (e.g., the first wiring layer 156a and the second wiring layer 156b).

For example, the capping layer 158 may be entirely disposed on a first interlayer insulation layer 152a and the first wiring layer 156a, the capacitor 160 and a second interlayer insulation layer 152b may be disposed on the capping layer 158, and the second wiring layer 156b may be disposed in the second interlayer insulation layer 152b at a position spaced apart from the capacitor 160. The first interlayer insulation layer 152a and/or the first wiring layer 156a may be an interlayer insulation layer and/or a wiring layer between the substrate 110 and the capping layer 158, and the second interlayer insulation layer 152b and/or the second wiring layer 156b may be an interlayer insulation layer and/or a wiring layer on a surface (a lower surface in FIG. 6) of the capping layer 158 opposite to the substrate 110. The term of first, second, and/or the like may be used for distinguishing one from another, and the example embodiments are not limited thereto.

The capacitor 160 according to at least one example embodiment may be an in-pixel capacitor disposed to correspond to each pixel region PX to store an image signal and a reset signal of each pixel region PX in a global shutter operation and perform a correlated double sampling (CDS) function. Noise may be improved using the capacitor 160. However, the example embodiments are not limited thereto. In some example embodiments, the capacitor 160 may be provided to be used in any of various types or to perform any of various functions. For example, the capacitor 160 may be used in a digital pixel sensor type. The capacitor 160 may be provided to reduce noise and/or to achieve a high dynamic range (HDR) regardless of storing the image signal and the reset signal.

In at least one example embodiment, the capacitor 160 may include a plurality of electrodes 170, and an insulation layer 180 between the plurality of electrodes 170. The capacitor 160 may be a metal-insulator-metal (MIM) capacitor (an MIM capacitor). For example, the capacitor 160 may be a multi-layered MIM capacitor including a plurality of electrode layers. For example, a number of the plurality of electrodes 170 included in the capacitor 160 may be 2 or more (e.g., 3 or more), for example, 20 or less (e.g., 10 or less). However, the example embodiments are not limited thereto.

In at least one example embodiment, the capacitor 160 may extend in a horizontal direction (a direction parallel to an X-Y plane in the drawings) (e.g., a direction parallel to the first surface 111 of the substrate 110) to have a predetermined area. For example, the capacitor 160 may have a planar structure (or a flat structure). For example, the capacitor 160 may extend in the horizontal direction and have a relatively large area in a plan view, and may have a relatively small thickness in the thickness direction (the Z-axis direction in the drawings) of the image sensor 10. The capacitor 160 may not include a protrusion portion that protrudes from a horizontal portion in a direction opposite to the substrate 110 in the thickness direction (the Z-axis direction in the drawings) of the image sensor 10. When the capacitor 160 may have the planar structure as in the above, the capacitor 160 may have a simple structure and be formed by a relatively easy manufacturing process.

In at least one example embodiment, the image sensor 10 may have a two-layered stacking structure, and a space in which the capacitor 160 is disposed may be sufficient to accommodate the physical conditions associated with the capacitance of the capacitor 160 and the capacitor 160 of the planar structure may be easily applied. However, the example embodiments are not limited thereto. In some example embodiments, the image sensor 10 may have a single-layered stacking structure or a stacking structure of three or more layers, and the capacitor 160 may have the planar structure. In some example embodiments, the capacitor 160 may include the protrusion portion.

At least one of the plurality of electrodes 170 may include or be formed of a conductive material (e.g., a zero-band gap material and/or a material with a Fermi level in a conductive band). For example, the conductive material may include at least one of metal, a metal alloy, metal nitride, metal silicide, and/or a doped semiconductor material. The metal or the metal alloy may include or be formed of at least one of titanium, tungsten, molybdenum, tantalum, aluminum, copper, nickel, ruthenium, and/or cobalt, and the metal nitride may include or be formed of at least one of titanium nitride, tungsten nitride, molybdenum nitride, and/or tantalum nitride. At least one of the plurality of electrodes 170 may further include metal oxide or metal oxynitride in which the above material is oxidized. At least one of the plurality of electrodes 170 may include a single layer or a plurality of layers.

The insulation layer 180 may be a high dielectric constant insulation layer including a high dielectric constant material. For example, the insulation layer 180 may have a dielectric constant higher than a dielectric constant of the interlayer insulation layer 152 and/or the capping layer 158 of the wiring portion 150. Each insulation layer 180 may include a single layer or a plurality of layers. The high dielectric constant material may have a dielectric constant higher than a dielectric constant of silicon oxide. The insulation layer 180 may include or be formed of at least one of an oxide, an oxynitride, and/or the like including at least one of hafnium, lanthanum, aluminum, zirconium, tantalum, titanium, barium, strontium, yttrium, and/or the like. For example, the insulation layer 180 may include or be formed of at least one of hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and/or lead scandium tantalum oxide (PbScTaO).

The capping layer 158 may include an insulator material. For example, the insulator material may be a material the same as or different from a material of the interlayer insulation layer 152 of the wiring portion 150, and may include or be formed of silicon oxide, silicon nitride, silicon oxynitride, and/or a low dielectric constant material. In some example embodiments, the capping layer 158 may not be additionally provided, and a portion of the interlayer insulation layer 152 may constitute the capping layer 158.

It is described as an example that the plurality of electrodes 170 include a first electrode 171, a second electrode 172, a third electrode 173, a fourth electrode 174, and a fifth electrode 175 sequentially formed. In the specification, the term of first, second, third, fourth, fifth, and/or the like may be used for distinguishing one from another, and the example embodiments are not limited thereto.

Referring to FIG. 7 and FIG. 8 together with FIG. 5 and FIG. 6, an electrical connection structure between the capacitor 160 according to at least one example embodiment and the capacitor contact vias 154a and 154b will be described.

FIG. 7 is a partial cross-sectional view taken along a line D-D′ in FIG. 5. FIG. 8 is a partial cross-sectional view taken along a line E-E′ in FIG. 5. FIG. 7 and FIG. 8 illustrate a portion corresponding to FIG. 6.

Referring to FIG. 5 to FIG. 8, in at least one example embodiment, the plurality of electrodes 170 may include a first electrode group 1710 and a second electrode group 1720. The first electrode group 1710 may include a plurality of first electrode layers electrically connected to each other. The second electrode group 1720 may include a plurality of second electrode layers electrically connected to each other and may be electrically insulated from the first electrode group 1710. Electrodes (e.g., first electrode layers) included in the first electrode group 1710 and electrodes (e.g., second electrode layers) included in the second electrode group 1720 may be alternately disposed.

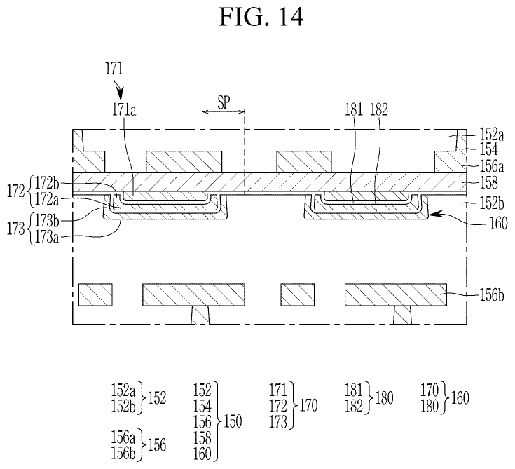

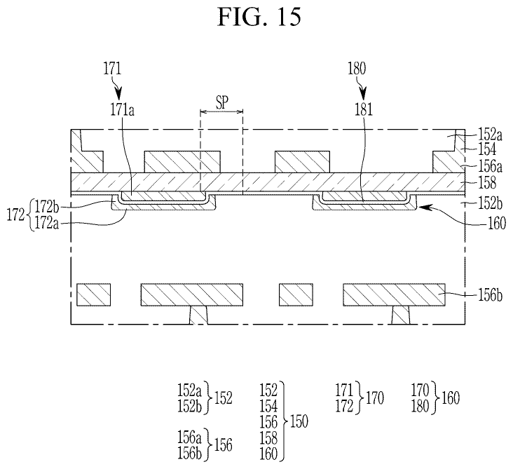

In at least one example embodiment, the first electrode 171, the third electrode 173, and the fifth electrode 175 may be the plurality of first electrode layers or the first electrode group 1710 electrically connected to each other, and the second electrode 172 and the fourth electrode 174 may be the plurality of second electrode layers or the second electrode group 1720 electrically connected to each other. That is, in at least one example embodiment, the first electrode group 1710 may include the plurality of first electrode layers electrically connected to each other, and the second electrode group 1720 may include the plurality of second electrode layers electrically connected to each other. However, the example embodiments are not limited thereto. Embodiments will be described later with reference to FIG. 14 and FIG. 15.

In at least one example embodiment, the capacitor 160 and the capacitor contact vias 154a and 154b may be electrically connected to have a through via type. For example, the capacitor contact vias 154a and 154b may include a first contact via 154a and a second contact via 154b. The first contact via 154a may be electrically connected to the first electrode group 1710 inside the plurality of electrodes 170, and may be electrically insulated from the second electrode group 1720. The second contact via 154b may be electrically connected to the second electrode group 1720 inside the plurality of electrodes 170, and may be electrically insulated from the first electrode group 1710. The phrase that the first or second contact via 154a or 154b is inside the plurality of electrodes 170 may refer to that the first or second contact via 154a or 154b is disposed inside an outer edge of the plurality of electrodes 170.

For example, the first contact via 154a may pass through a first position of at least one horizontal portion of the plurality of electrodes 170 (e.g., first to fifth horizontal portions 171a, 172a, 173a, 174a, and 175a). When the first electrode group 1710 includes the plurality of first electrode layers (e.g., the first electrode 171, the third electrode 173, and the fifth electrode 175), the plurality of first electrode layers (e.g., the first electrode 171, the third electrode 173, and the fifth electrode 175) may be electrically connected to (e.g., in contact with) one first contact via 154a together.

For example, the second contact via 154b may pass through a second position of at least one horizontal portion of the plurality of electrodes 170 (e.g., the first to fifth horizontal portions 171a, 172a, 173a, 174a, and 175a). In a plan view, the second position may be spaced apart from the first position. When the second electrode group 1720 includes the plurality of second electrode layers (e.g., the second electrode 172 and the fourth electrode 174), the plurality of second electrode layers (e.g., the second electrode 172 and the fourth electrode 174) may be electrically connected to (e.g., in contact with) one second contact via 154b together.

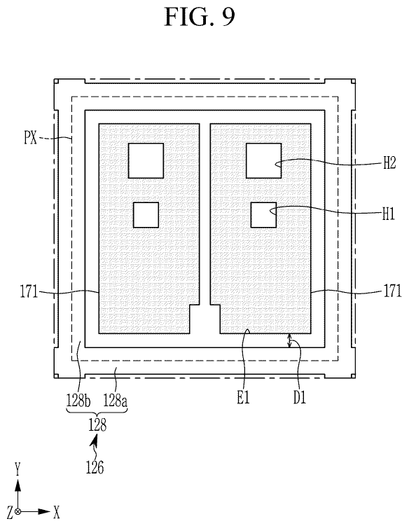

Referring to FIG. 9 together with FIG. 5 to FIG. 8, the first electrode 171 of the capacitor 160 according to at least one example embodiment will be described in detail.

FIG. 9 is a rear plan view schematically illustrating the first electrode 171 of the capacitor 160 in each pixel region PX of the image sensor 10 illustrated in FIG. 4. For a clear understanding and simple illustration, FIG. 9 mainly illustrates the second isolation pattern 128 and the first electrode 171 of the capacitor 160.

Referring to FIG. 5 to FIG. 9, in at least one example embodiment, the first electrode 171 of the capacitor 160 may include a first horizontal portion 171a.

For example, the entirety of the first electrode 171 may be formed of the first horizontal portion 171a, and may not include a portion extending in a direction that intersects the first horizontal portion 171a. That is, the first electrode 171 may not include a portion corresponding to a first side portion extending in a direction that intersects the first horizontal portion 171a. However, the example embodiments are not limited thereto. In some example embodiments, the first electrode 171 may include the portion corresponding to the first side portion.

In at least one example embodiment, in a plan view, the first outer edge E1 of the first electrode 171 may be spaced apart from the isolation pattern 126 (e.g., the second isolation pattern 128) with a first distance D1 that is relatively large. The first distance D1 may refer to a minimum distance between the first outer edge E1 of the first electrode 171 and the second isolation pattern 128 in a plan view.

In FIG. 9, it is illustrated as an example that a distance between the first outer edge E1 (e.g., a left edge or a right edge) of the first electrode 171 and the second extension portion 128b in the first direction (the X-axis direction in the drawings) is the first distance D1, and a distance between the first outer edge E1 (e.g., an upper edge or a lower edge) of the first electrode 171 and the first extension portion 128a in the second direction (the Y-axis direction in the drawings) is the first distance D1. However, the example embodiments are not limited thereto. In some example embodiments, a distance between the first outer edge E1 of the first electrode 171 and the second isolation pattern 128 in the first direction may be different from a distance between the first outer edge E1 of the first electrode 171 and the second isolation pattern 128 in the second direction.

The first horizontal portion 171a of the first electrode 171 may have a first hole H1 and a second hole H2. The first hole H1 may be disposed at the first position and the first contact via 154a may pass through the first hole H1. The second hole H2 may be disposed at the second position and the second contact via 154b may pass through the second hole H2. The second hole H2 may have an area greater than an area of the first hole H1.

The first hole H1 may have an area the same as and/or substantially similar to an area of the first contact via 154a, and an inner edge of the first electrode 171 may be connected to (e.g., in contact with) the first contact via 154a at a periphery of the first contact via 154a. The second hole H2 may have an area greater than an area of the second contact via 154b, and an inner edge of the first electrode 171 may be spaced apart from the second contact via 154b by a predetermined interval at a periphery of the second contact via 154b. Thereby, the first electrode 171 included in the first electrode group 1710 may be electrically connected to the first contact via 154a and may be electrically insulated from the second contact via 154b.

A first insulation layer 181 may cover at least an upper surface and an outer side surface of the first electrode 171 (e.g., the first horizontal portion 171a). The upper surface of the first electrode 171 or the first horizontal portion 171a may be a surface of the first electrode 171 or the first horizontal portion 171a opposite to the substrate 110 or the capping layer 158. The outer side surface of the first electrode 171 or the first horizontal portion 171a may be a side surface at an outer edge of the first electrode 171 or the first horizontal portion 171a. The first insulation layer 181 may not be disposed on an inner side surface at an inner edge of the first electrode 171 adjacent to the first hole H1, and may be disposed on an inner side surface at an inner edge of the first electrode 171 adjacent to the second hole H2.

For example, the first insulation layer 181 may include a first insulating horizontal portion and a first insulating side portion. The first insulating horizontal portion may be disposed on the upper surface of the first horizontal portion 171a. The first insulating side portion may extend in a direction that intersects the first insulating horizontal portion and may be disposed on a side surface of the first horizontal portion 171a. The first insulation layer 181 may further include an outer extension portion that is disposed on the capping layer 158 outside the first electrode 171. However, the example embodiments are not limited thereto. In some example embodiments, the first insulation layer 181 may not include the outer extension portion.

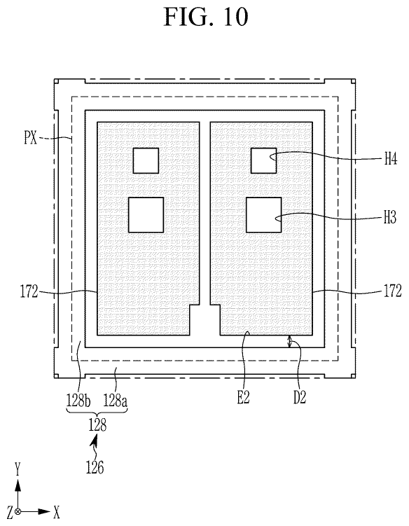

Referring to FIG. 10 together with FIG. 5 to FIG. 8, the second electrode 172 of the capacitor 160 according to at least one example embodiment will be described in detail.

FIG. 10 is a rear plan view schematically illustrating the second electrode 172 of the capacitor 160 in each pixel region PX of the image sensor 10 illustrated in FIG. 4. For a clear understanding and simple illustration, FIG. 10 mainly illustrates the second isolation pattern 128 and the second electrode 172 of the capacitor 160.

Referring to FIG. 5 to FIG. 8, and FIG. 10, the second electrode 172 may be disposed at least on the upper surface and the outer side surface of the first electrode 171 while interposing the first insulation layer 181 therebetween.

For example, the second electrode 172 may include a second horizontal portion 172a and a second side portion 172b. The second horizontal portion 172a may be disposed on the upper surface of the first horizontal portion 171a while interposing the first insulation layer 181 (e.g., the first insulating horizontal portion) therebetween and extend in a horizontal direction. The second side portion 172b may extend in a direction that intersects the second horizontal portion 172a, and may be disposed on the side surface of the first horizontal portion 171a while interposing the first insulation layer 181 (e.g., the first insulating side portion) therebetween.

That is, the second horizontal portion 172a may face the first horizontal portion 171a while interposing the first insulation layer 181 (e.g., the first insulating horizontal portion) therebetween to form a horizontal capacitor portion. The second side portion 172b may face the side surface of the first horizontal portion 171a while interposing the first insulation layer 181 (e.g., the first insulating side portion) therebetween to form a side capacitor portion.

The second side portion 172b of the second electrode 172 may constitute a second outer edge E2 of the second electrode 172. That is, the second electrode 172 may be disposed on the capping layer 158 and/or the outer extension portion of the first insulation layer 181 outside the first electrode 171 to have a distance corresponding to a thickness T2 of the second side portion 172b, and may not include a portion extending to an outside in a horizontal direction. Thereby, a defect, an impurity, and/or the like that may induced when the second electrode 172 includes the portion extending to the outside in the horizontal direction may be prevented.

In at least one example embodiment, the second electrode 172 may include the second side portion 172b, and the second outer edge E2 of the second electrode 172 may be disposed outside the first outer edge E1 of the first electrode 171 in a plan view. For example, the second outer edge E2 of the second electrode 172 may be disposed outside the first outer edge E1 of the first electrode 171 by the thickness T2 of the second electrode 172 (e.g., the second side portion 172b).

In at least one example embodiment, in a plan view, the second outer edge E2 of the second electrode 172 may be spaced apart from the isolation pattern 126 (e.g., the second isolation pattern 128) by a second distance D2 less than the first distance D1. The second distance D2 may refer to a minimum distance between the second outer edge E2 of the second electrode 172 and the second isolation pattern 128 in a plan view. For example, the second distance D2 may be a value obtained by subtracting the thickness T2 of the second electrode 172 (e.g., the second side portion 172b) from the first distance D1.

In FIG. 10, it is illustrated as an example that a distance between the second outer edge E2 (e.g., a left edge or a right edge) of the second electrode 172 and the second extension portion 128b in the first direction (the X-axis direction in the drawings) is the second distance D2, and a distance between the second outer edge E2 (e.g., an upper edge or a lower edge) of the second electrode 172 and the first extension portion 128a in the second direction (the Y-axis direction in the drawings) is the second distance D2. However, the example embodiments are not limited thereto. In some example embodiments, a distance between the second outer edge E2 of the second electrode 171 and the second isolation pattern 128 in the first direction may be different from a distance between the second outer edge E2 of the second electrode 171 and the second isolation pattern 128 in the second direction.

The second horizontal portion 172a of the second electrode 172 may have a third hole H3 and a fourth hole H4. The third hole H3 may be disposed at the first position and the first contact via 154a may pass through the third hole H3. The fourth hole H4 may be disposed at the second position and the second contact via 154b may pass through the fourth hole H4. The fourth hole H4 may have an area less than an area of the third hole H3.

The third hole H3 may have an area greater than an area of the first contact via 154a, and an inner edge of the second electrode 172 may be spaced apart from the first contact via 154a by a predetermined interval at a periphery of the first contact via 154a. The fourth hole H4 may have an area the same as and/or substantially similar to an area of the second contact via 154b, and an inner edge of the second electrode 172 may be connected to (e.g., in contact with) the second contact via 154b at a periphery of the second contact via 154b. Thereby, the second electrode 172 included in the second electrode group 1720 may be electrically insulated from the first contact via 154a and may be electrically connected to the second contact via 154b.

A second insulation layer 182 may cover at least an upper surface of the second electrode 172 (e.g., the second horizontal portion 172a) and an outer side surface of the second electrode 172 (e.g., the second side portion 172b). The upper surface of the second electrode 172 or the second horizontal portion 172a may be a surface of the second electrode 172 or the second horizontal portion 172a opposite to the substrate 110 or the capping layer 158. The outer side surface of the second electrode 172 may be a side surface at an outer edge of the second electrode 172. The second insulation layer 182 may be disposed on an inner side surface at an inner edge of the second electrode 172 adjacent to the third hole H3, and may not be disposed on an inner side surface at an inner edge of the second electrode 172 adjacent to the fourth hole H4.

For example, the second insulation layer 182 may include a second insulating horizontal portion and a second insulating side portion. The second insulating horizontal portion may be disposed on the upper surface of the second horizontal portion 172a. The second insulating side portion may extend in a direction that intersects the second insulating horizontal portion and may be disposed on the second side portion 172b. The second insulation layer 182 may further include or may not include an outer extension portion that is disposed on the outer extension portion of the first insulation layer 181.

Referring to FIG. 5 to FIG. 10, the third electrode 173, the fourth electrode 174, and the fifth electrode 175 of the capacitor 160 will be described in detail.

Referring to FIG. 5 to FIG. 10, the third electrode 173 may be disposed on an upper surface and an outer side surface of the second electrode 172 while interposing the second insulation layer 182 therebetween.

For example, the third electrode 173 may include a third horizontal portion 173a and a third side portion 173b. The third horizontal portion 173a may be disposed on the upper surface of the second horizontal portion 172a while interposing the second insulation layer 182 (e.g., the second insulating horizontal portion) therebetween and extend in a horizontal direction. The third side portion 173b may extend in a direction that intersects the third horizontal portion 173a, and may be disposed on the second side portion 172a while interposing the second insulation layer 182 (e.g., the second insulating side portion) therebetween.

That is, the third horizontal portion 173a may face the second horizontal portion 172a while interposing the second insulation layer 182 (e.g., the second insulating horizontal portion) therebetween to form the horizontal capacitor portion. The third side portion 173b may face the second side portion 172b while interposing the second insulation layer 182 (e.g., the second insulating side portion) therebetween to form the side capacitor portion.

The third side portion 173b of the third electrode 173 may constitute a third outer edge E3 of the third electrode 173. That is, the third electrode 173 may be disposed on the capping layer 158 and/or the outer extension portion of the first insulation layer 181 outside the second electrode 172 to have a distance corresponding to a thickness T3 of the third side portion 173b, and may not include a portion extending to an outside in a horizontal direction. Thereby, a defect, an impurity, and/or the like that may induced when the third electrode 173 includes the portion extending to the outside in the horizontal direction may be prevented.

In at least one example embodiment, the third electrode 173 may include the third side portion 173b, and the third outer edge E3 of the third electrode 173 may be disposed outside the second outer edge E2 of the second electrode 172 in a plan view. For example, the third outer edge E3 of the third electrode 173 may be disposed outside the second outer edge E2 of the second electrode 172 by the thickness T3 of the third electrode 173 (e.g., the third side portion 173b).

In at least one example embodiment, in a plan view, the third outer edge E3 of the third electrode 173 may be spaced apart from the isolation pattern 126 (e.g., the second isolation pattern 128) by a third distance less than the second distance D2. The third distance may refer to a minimum distance between the third outer edge E3 of the third electrode 173 and the second isolation pattern 128 in a plan view. For example, the third distance may be a value obtained by subtracting the thickness T3 of the third electrode 173 (e.g., the third side portion 173b) from the second distance D2.

The third horizontal portion 173a of the third electrode 173 may have a first hole H1 and a second hole H2. The first hole H1 may be disposed at the first position and the first contact via 154a may pass through the first hole H1. The second hole H2 may be disposed at the second position and the second contact via 154b may pass through the second hole H2. The second hole H2 may have an area greater than an area of the first hole H1.

The first hole H1 may have an area the same as and/or substantially similar to an area of the first contact via 154a, and an inner edge of the third electrode 173 may be connected to (e.g., in contact with) the first contact via 154a at a periphery of the first contact via 154a. The second hole H2 may have an area greater than an area of the second contact via 154b, and an inner edge of the third electrode 173 may be spaced apart from the second contact via 154b by a predetermined interval at a periphery of the second contact via 154b. Thereby, the third electrode 173 included in the first electrode group 1710 may be electrically connected to the first contact via 154a and may be electrically insulated from the second contact via 154b.

A third insulation layer 183 may cover at least an upper surface of the third electrode 173 (e.g., the third horizontal portion 173a) and an outer side surface of the third electrode 173 (e.g., the third side portion 173b). The upper surface of the third electrode 173 or the third horizontal portion 173a may be a surface of the third electrode 173 or the third horizontal portion 173a opposite to the substrate 110 or the capping layer 158. The outer side surface of the third electrode 173 may be a side surface at an outer edge of the third electrode 173. The third insulation layer 183 may not be disposed on an inner side surface at an inner edge of the third electrode 173 adjacent to the first hole H1, and may be disposed on an inner side surface at an inner edge of the third electrode 173 adjacent to the second hole H2.

For example, the third insulation layer 183 may include a third insulating horizontal portion and a third insulating side portion. The third insulating horizontal portion may be disposed on the upper surface of the third horizontal portion 173a. The third insulating side portion may extend in a direction that intersects the third insulating horizontal portion and may be disposed on the third side portion 173b. The third insulation layer 183 may further include or may not include an outer extension portion that is disposed on the outer extension portion of the first insulation layer 181.

The fourth electrode 174 may be disposed at least on the upper surface and the outer side surface of the third electrode 173 while interposing the third insulation layer 183 therebetween.

For example, the fourth electrode 174 may include a fourth horizontal portion 174a and a fourth side portion 174b. The fourth horizontal portion 174a may be disposed on the upper surface of the third horizontal portion 173a while interposing the third insulation layer 183 (e.g., the third insulating horizontal portion) therebetween and extend in a horizontal direction. The fourth side portion 174b may extend in a direction that intersects the fourth horizontal portion 174a, and may be disposed on the third side portion 173b while interposing the third insulation layer 183 (e.g., the third insulating side portion) therebetween.

That is, the fourth horizontal portion 174a may face the third horizontal portion 173a while interposing the third insulation layer 183 (e.g., the third insulating horizontal portion) therebetween to form the horizontal capacitor portion. The fourth side portion 174b may face the third side portion 173b while interposing the third insulation layer 183 (e.g., the third insulating side portion) therebetween to form the side capacitor portion.

The fourth side portion 174b of the fourth electrode 174 may constitute a fourth outer edge E4 of the fourth electrode 174. That is, the fourth electrode 174 may be disposed on the capping layer 158 and/or the outer extension portion of the first insulation layer 181 outside the third electrode 173 to have a distance corresponding to a thickness T4 of the fourth side portion 174b, and may not include a portion extending to an outside in a horizontal direction. Thereby, a defect, an impurity, and/or the like that may induced when the fourth electrode 174 includes the portion extending to the outside in the horizontal direction may be prevented.

In at least one example embodiment, the fourth electrode 174 may include the fourth side portion 174b, and the fourth outer edge E4 of the fourth electrode 174 may be disposed outside the third outer edge E3 of the third electrode 173 in a plan view. For example, the fourth outer edge E4 of the fourth electrode 174 may be disposed outside the third outer edge E3 of the third electrode 173 by the thickness T4 of the fourth electrode 174 (e.g., the fourth side portion 174b).

In at least one example embodiment, in a plan view, the fourth outer edge E4 of the fourth electrode 174 may be spaced apart from the isolation pattern 126 (e.g., the second isolation pattern 128) by a fourth distance less than the third distance. The fourth distance may refer to a minimum distance between the fourth outer edge E4 of the fourth electrode 174 and the second isolation pattern 128 in a plan view. For example, the fourth distance may be a value obtained by subtracting the thickness T4 of the fourth electrode 174 (e.g., the fourth side portion 174b) from the third distance.

The fourth horizontal portion 174a of the fourth electrode 174 may have a third hole H3 and a fourth hole H4. The third hole H3 may be disposed at the first position and the first contact via 154a may pass through the third hole H3. The fourth hole H4 may be disposed at the second position and the second contact via 154b may pass through the fourth hole H4. The fourth hole H4 may have an area less than an area of the third hole H3.

The third hole H3 may have an area greater than an area of the first contact via 154a, and an inner edge of the fourth electrode 174 may be spaced apart from the first contact via 154a by a predetermined interval at a periphery of the first contact via 154a. The fourth hole H4 may have an area the same as and/or substantially similar to an area of the second contact via 154b, and an inner edge of the fourth electrode 174 may be connected to (e.g., in contact with) the second contact via 154b at a periphery of the second contact via 154b. Thereby, the fourth electrode 174 included in the second electrode group 1720 may be electrically insulated from the first contact via 154a and may be electrically connected to the second contact via 154b.

A fourth insulation layer 184 may cover at least an upper surface of the fourth electrode 174 (e.g., the fourth horizontal portion 174a) and an outer side surface of the fourth electrode 174 (e.g., the fourth side portion 174b). The upper surface of the fourth electrode 174 or the fourth horizontal portion 174a may be a surface of the fourth electrode 174 or the fourth horizontal portion 174a opposite to the substrate 110 or the capping layer 158. The outer side surface of the fourth electrode 174 may be a side surface at an outer edge of the fourth electrode 174. The fourth insulation layer 184 may be disposed on an inner side surface at an inner edge of the fourth electrode 174 adjacent to the third hole H3, and may not be disposed on an inner side surface at an inner edge of the fourth electrode 174 adjacent to the fourth hole H4.

For example, the fourth insulation layer 184 may include a fourth insulating horizontal portion and a fourth insulating side portion. The fourth insulating horizontal portion may be disposed on the upper surface of the fourth horizontal portion 174a. The fourth insulating side portion may extend in a direction that intersects the fourth insulating horizontal portion and may be disposed on the fourth side portion 174b. The fourth insulation layer 184 may further include or may not include an outer extension portion that is disposed on the outer extension portion of the first insulation layer 181.

The fifth electrode 175 may be disposed on an upper surface and an outer side surface of the fourth electrode 174 while interposing the fourth insulation layer 184 therebetween.

For example, the fifth electrode 175 may include a fifth horizontal portion 175a and a fifth side portion 175b. The fifth horizontal portion 175a may be disposed on the upper surface of the fourth horizontal portion 174a while interposing the fourth insulation layer 184 (e.g., the fourth insulating horizontal portion) therebetween and extend in a horizontal direction. The fifth side portion 175b may extend in a direction that intersects the fifth horizontal portion 175a, and may be disposed on the fourth side portion 174b while interposing the fourth insulation layer 184 (e.g., the fourth insulating side portion) therebetween.

That is, the fifth horizontal portion 175a may face the fourth horizontal portion 174a while interposing the fourth insulation layer 184 (e.g., the fourth insulating horizontal portion) therebetween to form the horizontal capacitor portion. The fifth side portion 175b may face the fourth side portion 174b while interposing the fourth insulation layer 184 (e.g., the fourth insulating side portion) therebetween to form the side capacitor portion.

The fifth side portion 175b of the fifth electrode 175 may constitute a fifth outer edge E5 of the fifth electrode 175. That is, the fifth electrode 175 may be disposed on the capping layer 158 and/or the outer extension portion of the first insulation layer 181 outside the fourth electrode 174 to have a distance corresponding to a thickness T5 of the fifth side portion 175b, and may not include a portion extending to an outside in a horizontal direction. Thereby, a defect, an impurity, and/or the like that may induced when the fifth electrode 175 includes the portion extending to the outside in the horizontal direction may be prevented.

In at least one example embodiment, the fifth electrode 175 may include the fifth side portion 175b, and the fifth outer edge E5 of the fifth electrode 175 may be disposed outside the fourth outer edge E4 of the fourth electrode 174 in a plan view. For example, the fifth outer edge E5 of the fifth electrode 175 may be disposed outside the fourth outer edge E4 of the fourth electrode 174 by the thickness T5 of the fifth electrode 175 (e.g., the fifth side portion 175b).

In at least one example embodiment, in a plan view, the fifth outer edge E5 of the fifth electrode 175 may be spaced apart from the isolation pattern 126 (e.g., the second isolation pattern 128) by a fifth distance less than the fourth distance. The fifth distance may refer to a minimum distance between the fifth outer edge E5 of the fifth electrode 175 and the second isolation pattern 128 in a plan view. For example, the fifth distance may be a value obtained by subtracting the thickness T5 of the fifth electrode 175 (e.g., the fifth side portion 175b) from the fourth distance.

The fifth horizontal portion 175a of the fifth electrode 175 may have a first hole H1 and a second hole H2. The first hole H1 may be disposed at the first position and the first contact via 154a may pass through the first hole H1. The second hole H2 may be disposed at the second position and the second contact via 154b may pass through the second hole H2. The second hole H2 may have an area greater than an area of the first hole H1.

The first hole H1 may have an area the same as and/or substantially similar to an area of the first contact via 154a, and an inner edge of the fifth electrode 175 may be connected to (e.g., in contact with) the first contact via 154a at a periphery of the first contact via 154a. The second hole H2 may have an area greater than an area of the second contact via 154b, and an inner edge of the fifth electrode 175 may be spaced apart from the second contact via 154b by a predetermined interval at a periphery of the second contact via 154b. Thereby, the fifth electrode 175 included in the first electrode group 1710 may be electrically connected to the first contact via 154a and may be electrically insulated from the second contact via 154b.

The interlayer insulation layer 152 of the wiring portion 150 (e.g., the second interlayer insulation layer 152b) may cover the capacitor 160 in a region other than the capacitor contact vias 154a and 154b.

In at least one example embodiment, the electrodes 170 included in the capacitor 160, a thickness of a side portion (e.g., the second, third, fourth, and/or fifth side portion 172b, 173b, 174b, and/or 175b) may be same as, less than, or greater than a thickness of a horizontal portion (e.g., the second, third, fourth, and/or fifth horizontal portion 172a, 173a, 174a, and/or 175a).

As described in the above, in at least one example embodiment, in a plan view, an upper electrode may have an area greater than an area of a lower electrode, and an outer edge of the upper electrode may be disposed outside an outer edge of the lower electrode. The lower electrode may refer to an electrode formed earlier in a manufacturing process or disposed relatively closer to the substrate 110 or the capping layer 158, and the upper electrode may refer to an electrode formed later in a manufacturing process or disposed relatively far away from the substrate 110 or the capping layer 158. The area may refer to an entire area inside an outer edge of each electrode.

For example, in a plan view, the second electrode 172 of the upper electrode may have an area greater than an area of the first electrode 171 of the lower electrode, and the second outer edge E2 of the second electrode 172 of the upper electrode may be disposed outside the first outer edge E1 of the first electrode 171 of the lower electrode. For example, in a plan view, the third electrode 173 of the upper electrode may have an area greater than an area of the second electrode 172 of the lower electrode, and the third outer edge E3 of the third electrode 173 of the upper electrode may be disposed outside the second outer edge E2 of the second electrode 172 of the lower electrode. For example, in a plan view, the fourth electrode 174 of the upper electrode may have an area greater than an area of the third electrode 173 of the lower electrode, and the fourth outer edge E4 of the fourth electrode 174 of the upper electrode may be disposed outside the third outer edge E3 of the third electrode 173 of the lower electrode. For example, in a plan view, the fifth electrode 175 of the upper electrode may have an area greater than an area of the fourth electrode 174 of the lower electrode, and the fifth outer edge E5 of the fifth electrode 175 of the upper electrode may be disposed outside the fourth outer edge E4 of the fourth electrode 174 of the lower electrode.

Accordingly, the second electrode 172 of the upper electrode may entirely cover the first electrode 171 of the lower electrode. The third electrode 173 of the upper electrode may entirely cover the second electrode 172 of the lower electrode. The fourth electrode 174 of the upper electrode may entirely cover the third electrode 173 of the lower electrode. The fifth electrode 175 of the upper electrode may entirely cover the fourth electrode 174 of the lower electrode.

For example, in a plan view, from the first electrode 171 of the lowermost electrode to the fifth electrode 175 of the uppermost electrode, an area may increase sequentially and an outer edge may be sequentially disposed to an outside.

For example, a length of the upper electrode in the first direction (the X-axis direction in the drawings) may be greater than a length of the lower electrode in the first direction (the X-axis direction in the drawings), and/or a length of the upper electrode in the second direction (the Y-axis direction in the drawings) may be greater than a length of the lower electrode in the second direction (the Y-axis direction in the drawings). For example, from the first electrode 171 of the lowermost electrode to the fifth electrode 175 of the uppermost electrode, the length in the first direction and/or the length in the second direction may sequentially increase.

In at least one example embodiment, at least one of the plurality of electrodes 170 includes the side portion (e.g., the second to fifth side portions 172b, 173b, 174b, and 175b), and a side overlap portion SP where the plurality of electrodes 170 overlap may be provided at an outer side surface of the capacitor 160.

In at least one example embodiment, the side overlap portion SP, the first electrode group 1710 and the second electrode group 1720 may be stacked on each other to form the side capacitor portion. This may be different from a comparative example in which a plurality of electrode layers that are electrically connected to each other overlap each other and electrode layers in different electrode groups do not overlap and thus a side capacitor portion is not provided.

For example, in the side overlap portion SP, the first electrode 171 included in the first electrode group 1710 and the second electrode 172 included in the second electrode group 1720 may overlap each other. In the side overlap portion SP, the second electrode 172 included in the second electrode group 1720 and the third electrode 173 included in the first electrode group 1710 may overlap each other. In the side overlap portion SP, the third electrode 173 included in the first electrode group 1710 and the fourth electrode 174 included in the second electrode group 1720 may overlap each other. In the side overlap portion SP, the fourth electrode 174 included in the second electrode group 1720 and the fifth electrode 175 included in the first electrode group 1710 may overlap each other.

For example, the side overlap portion SP may have an entire overlap structure in which the plurality of electrodes 170 included in the first electrode group 1710 and the second electrode group 1720 overlap together.

In at least one example embodiment, the side overlap portion SP may be disposed at the entirety of an outer side surface of the capacitor 160 at the outer edge of the capacitor 160. For example, the side overlap portion SP may be disposed at the entirety of first to fourth edges (e.g., an upper edge, a lower edge, a left edge and a lower edge in FIG. 5) of the capacitor 160. Thereby, an area of the side overlap portion SP may increase and a capacitance of the capacitor 160 may largely increase. However, the example embodiments are not limited thereto. In some example embodiments, the side overlap portion SP may be disposed at least at a portion of the outer side surface of the capacitor 160.

In a plan view, two opposite portions of the side overlap portion SP at opposite sides in one direction may have a symmetrical shape. For example, two opposite portions of the side overlap portion SP that are disposed at opposite sides in the first direction (the X-axis direction in the drawings) and extend in the second direction (the Y-axis direction in the drawings) may have a symmetrical shape. For example, two opposite portions of the side overlap portion SP that are disposed at opposite sides in the second direction and extend in the first direction may have a symmetrical shape. However, the example embodiments are not limited thereto. In some example embodiments, the side overlap portion SP may be disposed at least at a portion of the outer side surface of the capacitor 160.

As described in the above, at the inner edge of the capacitor 160 adjacent to the first contact via 154a, electrodes included in the first electrode group 1710 (e.g., the first electrode 171, the third electrode 173, and the fifth electrode 175) may be electrically connected to (e.g. in contact with) the first contact via 154a, and electrodes included in the second electrode group 1720 (e.g., the second electrode 172 and the fourth electrode 174) may be spaced apart from the first contact via 154a. Accordingly, the inner edge of the capacitor 160 adjacent to the first contact via 154a may have a partial overlap structure in which a part of the plurality of electrodes 170 (e.g., the first electrode group 1710) overlaps, but another part of the plurality of electrodes 170 (e.g., the second electrode group 1720) does not overlap. That is, the inner edge of the capacitor 160 adjacent to the first contact via 154a may have a structure different from a structure of the side overlap portion SP.

As described in the above, at the inner edge of the capacitor 160 adjacent to the second contact via 154b, electrodes included in the second electrode group 1720 (e.g., the second electrode 172 and the fourth electrode 174) may be electrically connected to (e.g. in contact with) the second contact via 154b, and electrodes included in the first electrode group 1710 (e.g., the first electrode 171, the third electrode 173, and the fifth electrode 175) may be spaced apart from the first contact via 154a. Accordingly, the inner edge of the capacitor 160 adjacent to the second contact via 154b may have a partial overlap structure in which a part of the plurality of electrodes 170 (the second electrode group 1720) overlaps, but another part of the plurality of electrodes 170 (e.g., the first electrode group 1710) does not overlap. That is, the inner edge of the capacitor 160 adjacent to the second contact via 154b may have a structure different from a structure of the side overlap portion SP.

As described in the above, at least one of the plurality of electrodes 170 may include a horizontal portion and a side portion, wherein the horizontal portion overlaps another one of the plurality of electrodes 170 and extends in a horizontal direction, and the side portion may extend from the horizontal portion and is in the side overlap portion SP. The first contact via 154a may pass through the horizontal portion at the first position to be electrically connected to (e.g., in contact with) the first electrode group 1710 (e.g., the plurality of first electrode layers), and the second contact via 154b may pass through the horizontal portion at the second position different from the first position to be electrically connected to (e.g., in contact with) the second electrode group 1720 (e.g., the plurality of second electrode layers).

That is, in at least one example embodiment, the capacitor contact vias 154a and 154b may pass through the horizontal portion constituting the horizontal capacitor portion to be electrically connected to the capacitor 160 to have a through via type. Thereby, when at least one of the first electrode group 1710 and the second electrode group 1720 includes the plurality of electrode layers to include the plurality of electrodes 170 (e.g., three or more electrodes), an electrical connection structure may be simplified.

On the other hand, if a plurality of contact vias (e.g., three or more contact vias) corresponding to a plurality of electrodes (e.g., three or more electrodes), respectively, are included, portions where the plurality of electrodes and the plurality of contact vias are electrically connected, respectively, are necessary. Accordingly, an area of the portions where the plurality of electrodes and the plurality of contact vias are electrically connected and that do not constitute a capacitor portion may increase, and thus, an area of the capacitor portion may be difficult to increase.

In the drawings, it is illustrated as an example that each of the first contact via 154a and the second contact via 154b is disposed at a center of the capacitor 160 in the first direction (the X-axis direction in the drawings), the first contact via 154a is disposed at a central portion of the pixel region PX in the second direction (the Y-axis direction in the drawings), and the second contact via 154b is disposed at an upper portion of the pixel region PX in the second direction (the Y-axis direction in the drawings). However, the example embodiments are not limited thereto. In some example embodiments, a position of the first contact via 154a or the second contact via 154b may be variously modified.

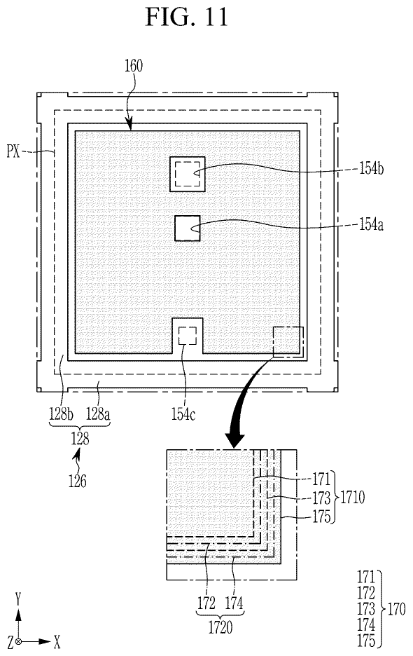

In the drawings, it is illustrated as an example that two capacitors 160 are included in each pixel region PX. However, the example embodiments are not limited thereto. In some example embodiments, a number of the capacitors 160 included in each pixel region PX may be variously modified. Embodiments will be described later in detail with reference to FIG. 11 to FIG. 13. In FIG. 5, it is illustrated as an example that a power contact via 154c is disposed at a lower portion between two capacitors 160 in each pixel region PX. However, the example embodiments are not limited thereto. In some example embodiments, a position of the power contact via 154c may be variously modified.

According to at least one example embodiment, the capacitor 160 may include the side overlap portion SP at the side surface (e.g., the outer side surface) at the edge (e.g., the outer edge) of the capacitor 160, and a capacitance of the capacitor 160 may increase without a major change in a manufacturing process. Accordingly, fixed pattern noise (FPN), random noise, and/or the like may be improved. A leakage current or a breakdown voltage may be maintained at a same level when the capacitance of the capacitor 160 is increased by the side overlap portion SP. Thereby, performance of the image sensor 10 may be improved.

A manufacturing method of the capacitor 160 according to at least one example embodiment will be briefly described. The first electrode 171 may be formed, and the first insulation layer 181 may be formed on the first electrode 171. The second electrode 172 may be formed to cover the upper surface and the side surface of the first electrode 171 on the first insulation layer 181, and the second insulation layer 182 may be formed on the second electrode 172. The third electrode 173 may be formed to cover the upper surface and the side surface of the second electrode 172 on the second insulation layer 182, and the third insulation layer 183 may be formed on the third electrode 173. The fourth electrode 174 may be formed to cover the upper surface and the side surface of the third electrode 173 on the third insulation layer 183, and the fourth insulation layer 184 may be formed on the fourth electrode 174. The fifth electrode 175 may be formed to cover the upper surface and the side surface of the fourth electrode 174 on the fourth insulation layer 184. Each of the plurality of electrodes 170 may be formed to have a pattern, and/or may have a desired shape through a patterning process. In at least one example embodiment, the capacitor 160 may be formed by forming the plurality of electrodes 170 to include the side overlap portion SP in which the first electrode group 1710 and the second electrode group 1720 are stacked.

Subsequently, the first contact via 154a that passes through the horizontal portions of the plurality of electrodes 170 at the first position and is electrically connected to the first electrode group 1710 and the second contact via 154b that passes through the horizontal portions of the plurality of electrodes 170 at the second position and is electrically connected to the second electrode group 1720 may be formed. For example, a through hole passing through the plurality of electrodes 170 may be formed in the process of forming the first contact via 154a and the through hole may constitute the first hole H1, and/or the first electrode group 1710 may be formed to have the first hole H1 in the process of forming the first electrode group 1710. For example, a through hole passing through the plurality of electrodes 170 may be formed in the process of forming the second contact via 154b and the through hole may constitute the fourth hole H4, and/or the second electrode group 1720 may be formed to have the fourth hole H4 in the process of forming the second electrode group 1720.

Hereinafter, referring to FIG. 11 to FIG. 15, image sensors and capacitors included therein will be described in more detail. To the extent that an element is not described in detail below, it may be understood that the element is at least similar to a corresponding element that has been described elsewhere within the present disclosure. A portion which is not described in the above will be described in detail.

FIG. 11 is a rear plan view schematically illustrating a capacitor in each pixel region of an image sensor according to at least one example embodiment. FIG. 11 illustrates a portion corresponding to FIG. 5.

Referring to FIG. 11, in at least one example embodiment, one capacitor 160 may be provided in each pixel region PX.

In FIG. 11, it is illustrated as an example that each of a first contact via 154a and a second contact via 154b is disposed at a center of the capacitor 160 or the pixel region PX in a first direction (an X-axis direction in the drawings), the first contact via 154a is disposed at a central portion of the pixel region PX in a second direction (a Y-axis direction in the drawings), and the second contact via 154b is disposed at an upper portion of the pixel region PX in the second direction (the Y-axis direction in the drawings). However, the example embodiments are not limited thereto. In some example embodiments, a position of the first contact via 154a or the second contact via 154b may be variously modified.

In FIG. 11, it is illustrated as an example that a power contact via 154c is disposed at a portion of a lower portion of the capacitor 160 in each pixel region PX. However, the example embodiments are not limited thereto. In some example embodiments, a position of the power contact via 154c may be variously modified.

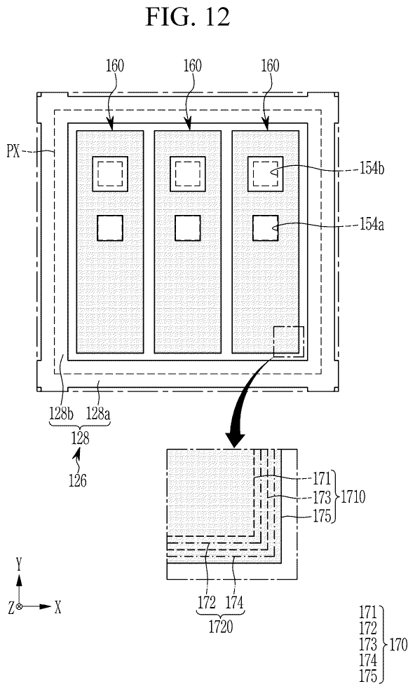

FIG. 12 is a rear plan view schematically illustrating a capacitor in each pixel region of an image sensor according to at least one example embodiment. FIG. 12 illustrates a portion corresponding to FIG. 5, and a power contact via is omitted in FIG. 12.

Referring to FIG. 12, in at least one example embodiment, three or more capacitors 160 may be provided in each pixel region PX. In FIG. 12, it is illustrated as an example that three capacitors 160 are provided in each pixel region PX, but the example embodiments are not limited thereto.

For example, a plurality of capacitors 160 may be disposed side by side in a first direction (an X-axis direction in the drawings), and each of the plurality of capacitors 160 may extend in a second direction (a Y-axis direction in the drawings). However, the example embodiments are not limited thereto. In some example embodiments, an arrangement of the plurality of capacitors 160 may be variously modified.

In FIG. 12, it is illustrated as an example that each of a first contact via 154a and a second contact via 154b is disposed at a center of the capacitor 160 in the first direction (the X-axis direction in the drawings), the first contact via 154a is disposed at a central portion of the pixel region PX in the second direction (the Y-axis direction in the drawings), and the second contact via 154b is disposed at an upper portion of the pixel region PX in the second direction (the Y-axis direction in the drawings). However, the example embodiments are not limited thereto. In some example embodiments, a position of the first contact via 154a or the second contact via 154b may be variously modified.

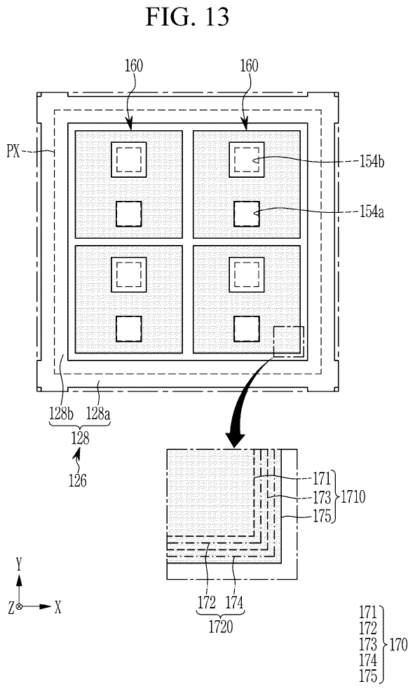

FIG. 13 is a rear plan view schematically illustrating a capacitor in each pixel region of an image sensor according to at least one example embodiment. FIG. 13 illustrates a portion corresponding to FIG. 5, and a power contact via is omitted in FIG. 13.

Referring to FIG. 13, in at least one example embodiment, three or more capacitors 160 may be provided in each pixel region PX. In FIG. 13, it is illustrated as an example that four capacitors 160 are provided in each pixel region PX, but the example embodiments are not limited thereto.

For example, a plurality of capacitors 160 may be disposed in a first direction (an X-axis direction in the drawings), and a plurality of capacitors 160 may be disposed in a second direction (a Y-axis direction in the drawings). That is, the plurality of capacitors 160 may be disposed to have a matrix shape in each pixel region PX. However, the example embodiments are not limited thereto. In some example embodiments, an arrangement of the plurality of capacitors 160 may be variously modified.

In FIG. 13, it is illustrated as an example that each of a first contact via 154a and a second contact via 154b is disposed at a center of the capacitor 160 in the first direction (the X-axis direction in the drawings), the first contact via 154a is disposed at a central portion of the capacitor 160 in the second direction (the Y-axis direction in the drawings), and the second contact via 154b is disposed at an upper portion of the capacitor 160 in the second direction (the Y-axis direction in the drawings). However, the example embodiments are not limited thereto. In some example embodiments, a position of the first contact via 154a or the second contact via 154b may be variously modified.

FIG. 14 is a partial cross-sectional view illustrating an image sensor according to at least one example embodiment. FIG. 14 illustrates a portion corresponding to FIG. 6.

Referring to FIG. 14, in at least one example embodiment, a first electrode group 1710 may include a plurality of first electrode layers, and a second electrode group 1720 may include one second electrode layer. The first electrode group 1710 may include a first electrode 171 and a third electrode 173, and the second electrode group 1720 may include a second electrode 172 disposed between the first electrode 171 and the third electrode 173. A first insulation layer 181 may be disposed between the first electrode 171 and the second electrode 172, and a second insulation layer 182 may be disposed between the second electrode 172 and the third electrode 173.

In at least one example embodiment, a capacitor 160 may include a side overlap portion SP in which the first electrode group 1710 and the second electrode group 1720 are stacked at a side surface of the capacitor 160. For example, in the side overlap portion SP, the first electrode 171, a second side portion 172b of the second electrode 172, and a third side portion 173b of the third electrode 173 may be sequentially disposed.

For example, a first contact via 154a may pass through at least one horizontal portion of the plurality of electrodes 170 (e.g., first to third horizontal portions 171a, 172a, and 173a) at a first position. When the first electrode group 1710 includes the plurality of first electrode layers (e.g., the first electrode 171 and the third electrode 173) as in the above, the plurality of first electrode layers (e.g., the first electrode 171 and the third electrode 173) may be electrically connected to (e.g., in contact with) one first contact via 154a together.

For example, the second contact via 154b may pass through at least one horizontal portion of the plurality of electrodes 170 (e.g., the first to third horizontal portions 171a, 172a, and 173a) at a second position. In a plan view, the second position may be spaced apart from the first position. When the second electrode group 1720 includes one second electrode layer (e.g., the second electrode 172) as in the above, one second electrode layer (e.g., the second electrode 172) may be electrically connected to (e.g., in contact with) one second contact via 154b.

A description of a first electrode 171, a second electrode 172, a third electrode 173, a first insulation layer 181, a second insulation layer 182, a first contact via 154a, and a second contact via 154b with reference to FIG. 1 to FIG. 10 may be applied to the first electrode 171, the second electrode 172, the third electrode 173, the first insulation layer 181, the second insulation layer 182, the first contact via 154a, and the second contact via 154b.

FIG. 15 is a partial cross-sectional view illustrating an image sensor according to at least one example embodiment. FIG. 15 illustrates a portion corresponding to FIG. 6.

Referring to FIG. 15, in at least one example embodiment, a first electrode group 1710 may include one first electrode layer, and a second electrode group 1720 may include one second electrode layer. The first electrode group 1710 may include a first electrode 171, and the second electrode group 1720 may include a second electrode 172 disposed on the first electrode 171. A first insulation layer 181 may be disposed between the first electrode 171 and the second electrode 172.

In at least one example embodiment, a capacitor 160 may include a side overlap portion SP in which the first electrode group 1710 and the second electrode group 1720 are stacked at a side surface of the capacitor 160. For example, in the side overlap portion SP, the first electrode 171 and a second side portion 172b of the second electrode 172 may be sequentially disposed.

For example, a first contact via 154a may pass through at least one horizontal portion of the plurality of electrodes 170 (e.g., first and second horizontal portions 171a and 172a) at a first position. When the first electrode group 1710 includes one first electrode layer (e.g., the first electrode 171) as in the above, one electrode layer (e.g., the first electrode 171) may be electrically connected to (e.g., in contact with) one first contact via 154a.

For example, the second contact via 154b may pass through at least one horizontal portion of the plurality of electrodes 170 (e.g., the first and second horizontal portions 171a and 172a) at a second position. In a plan view, the second position may be spaced apart from the first position. When the second electrode group 1720 includes one second electrode layer (e.g., the second electrode 172) as in the above, one second electrode layer (e.g., the second electrode 172) may be electrically connected to (e.g., in contact with) one second contact via 154b.

A description of a first electrode 171, a second electrode 172, a first insulation layer 181, a first contact via 154a, and a second contact via 154b with reference to FIG. 1 to FIG. 10 may be applied to the first electrode 171, the second electrode 172, the first insulation layer 181, the first contact via 154a, and the second contact via 154b.

According to at least one example embodiment, is provided a manufacturing method of a capacitor such that the capacitor including a plurality of electrodes and an insulation layer between the plurality of electrodes is formed. The plurality of electrodes include a first electrode group and a second electrode group electrically insulated from each other. At least one of the first electrode group and the second electrode group includes a plurality of electrode layers electrically connected to each other. The plurality of electrodes are formed to include a side overlap portion in which the first electrode group and the second electrode group are stacked.

While some examples have been described in connection with what is presently considered to be some practical embodiments, it is to be understood that the disclosure is not limited to the disclosed embodiments, and that the disclosure is intended to cover various modifications and equivalent arrangements included within the spirit and scope of the appended claims.

What is claimed is:

1. An image sensor, comprising:
a substrate having a first surface and a second surface, the second surface opposite to the first surface;
a plurality of pixel regions, each of the plurality of pixel regions including a photodiode in the substrate and a pixel circuit at the first surface of the substrate; and
a wiring portion on the first surface of the substrate and electrically connected to the pixel circuit, the wiring portion including a capacitor, the capacitor including a plurality of electrodes and an insulation layer between the plurality of electrodes,
wherein the plurality of electrodes include a first electrode group and a second electrode group,
wherein the insulation layer electrically insulates the first electrode group from the second electrode group,
wherein at least one of the first electrode group and the second electrode group includes a plurality of electrode layers electrically connected to each other, and
wherein the capacitor includes a side overlap portion in which the first electrode group and the second electrode group are stacked at a side surface of the capacitor.

2. The image sensor of claim 1, wherein the side overlap portion has an entire overlap structure such that the plurality of electrodes overlap together in a horizontal direction.

3. The image sensor of claim 1, wherein the side surface of the capacitor is an outer side surface at an outer edge of the capacitor, and the side overlap portion is at an entirety of the outer side surface of the capacitor.

4. The image sensor of claim 1, wherein the plurality of electrodes include:
a first electrode including a first horizontal portion,
a second electrode including a second horizontal portion and a second side portion, the second horizontal portion on the first horizontal portion and the second side portion facing a side surface of the first horizontal portion, and
a third electrode including a third horizontal portion and a third side portion, the third horizontal portion on the second horizontal portion and the third side portion facing the second side portion.

5. The image sensor of claim 4, wherein the first electrode group includes the first electrode and the third electrode,
the first electrode and the third electrode are electrically connected to each other, and
the second electrode group includes the second electrode.

6. The image sensor of claim 4, wherein, in a plan view, an outer edge of the second electrode is outside of an outer edge of the first electrode, and an outer edge of the third electrode is outside of the outer edge of the second electrode.

7. The image sensor of claim 4, wherein, in a plan view, at least one of the second side portion constitutes an outer edge of the second electrode, or the third side portion constitutes an outer edge of the third electrode.

8. The image sensor of claim 1, wherein at least one of the plurality of electrodes includes a horizontal portion and a side portion,
wherein the horizontal portion of the at least one of the plurality of electrodes overlaps another one of the plurality of electrodes and extends in a horizontal direction,
wherein the side portion extends from the horizontal portion and is at the side overlap portion, and
wherein the wiring portion includes a capacitor contact via, the capacitor contact via passing through the horizontal portion to be electrically connected to one of the first electrode group or the second electrode group and to be electrically insulated from a remaining one of the first electrode group or the second electrode group.

9. The image sensor of claim 8, wherein the capacitor contact via is a first capacitor contact via, and the image sensor includes a second capacitor contact via,
wherein the first capacitor contact via passes through a first position of the horizontal portion and is electrically connected to the first electrode group, and
wherein the second capacitor contact via passes through a second position of the horizontal portion different form the first position and is electrically connected to the second electrode group.

10. The image sensor of claim 8, wherein a structure of an inner edge of the capacitor is different from a structure of the side overlap portion, and
wherein the inner edge of the capacitor is facing the capacitor contact via such that the capacitor contact via is closer to the inner edge than to the side overlap portion.

11. The image sensor of claim 8, wherein an inner edge of the capacitor has a partial overlap structure in which a part of the plurality of electrodes overlaps, and
wherein the inner edge of the capacitor is facing the capacitor contact via such that the capacitor contact via is closer to the inner edge than to the side overlap portion.

12. The image sensor of claim 8, wherein the plurality of electrode layers included in one of the first electrode group or the second electrode group are each electrically connected to the capacitor contact via.

13. An image sensor, comprising:
a substrate having a first surface and a second surface, the second surface opposite to the first surface;
a plurality of pixel regions, each of the plurality of pixel regions including a photodiode in the substrate and a pixel circuit at the first surface of the substrate; and
a wiring portion on the first surface of the substrate and electrically connected to the pixel circuit, the wiring portion including a capacitor,
the capacitor including a plurality of electrodes and an insulation layer between the plurality of electrodes,
wherein the capacitor includes a side overlap portion in which the plurality of electrodes are stacked at a side surface of the capacitor,
wherein the plurality of electrodes include at least a first electrode and a second electrode,
wherein the first electrode includes a first horizontal portion,
wherein the second electrode includes a second horizontal portion and a second side portion, the second horizontal portion on the first horizontal portion and the second side portion facing a side surface of the first horizontal portion, and
wherein the wiring portion includes a capacitor contact via passing through at least one of the first horizontal portion and the second horizontal portion and electrically connected to the first electrode or the second electrode.

14. The image sensor of claim 13, wherein the capacitor contact via is a first capacitor contact via and the image sensor further includes a second capacitor contact via,
wherein the first capacitor contact via passes through at least one of the first horizontal portion and the second horizontal portion at a first position and is electrically connected to the first electrode, and
wherein the second capacitor contact via passes through at least one of the first horizontal portion and the second horizontal portion at a second position different form the first position and is electrically connected to the second electrode.

15. The image sensor of claim 13, wherein an outer edge of the second electrode is an outside an outer edge of the first electrode.

16. The image sensor of claim 13, wherein the side overlap portion has an entire overlap structure such that the plurality of electrodes overlap in a horizontal direction.

17. The image sensor of claim 13, wherein a structure of an inner edge of the capacitor is different from a structure of the side overlap portion, and
wherein the inner edge of the capacitor is facing the capacitor contact via such that the capacitor contact via is closer to the inner edge than to the side overlap portion.

18. The image sensor of claim 13, wherein an inner edge of the capacitor has a partial overlap structure in which a part of the plurality of electrodes overlaps, and
wherein the inner edge of the capacitor is facing the capacitor contact via such that the capacitor contact via is closer to the inner edge than to the side overlap portion.

19. A capacitor, comprising:
a plurality of electrodes including a first electrode group and a second electrode group, the second electrode group electrically insulated from the first electrode group; and
an insulation layer between the plurality of electrodes,
wherein at least one of the first electrode group and the second electrode group includes a plurality of electrode layers electrically connected to each other, and
wherein the capacitor includes a side overlap portion in which the first electrode group and the second electrode group are stacked at a side surface of the capacitor.

20. The capacitor of claim 19, wherein the side overlap portion has an entire overlap structure such that the plurality of electrodes overlap together in a horizontal direction.
